(19) United States
(12) Patent Application Publication
(10) Pub. No.: US 2025/0344542 A1
(43) Pub. Date: Nov. 6, 2025

(54) HIGH PERFORMANCE STACKING PIXEL

(71) Applicant: Taiwan Semiconductor Manufacturing Company, Ltd., Hsinchu (TW)

(72) Inventors: Hsin-Hung Chen, Tainan City (TW); Wen-I Hsu, Tainan City (TW); Feng-Chi Hung, Chu-Bei City (TW); Jen-Cheng Liu, Hsin-Chu City (TW); Dun-Nian Yaung, Taipei City (TW)

(21) Appl. No.: 19/271,846

(22) Filed: Jul. 17, 2025

Related U.S. Application Data
(63) Continuation of application No. 18/401,771, filed on Jan. 2, 2024.
(60) Provisional application No. 63/594,445, filed on Oct. 31, 2023.

(51) Int. Cl. H10F 39/00

(52) U.S. Cl. CPC H10F 39/809; H10F 39/018; H10F 39/811

(57) ABSTRACT

The present disclosure relates to a multi-dimensional image sensor integrated chip (IC) structure. The multi-dimensional image sensor IC structure includes a plurality of image sensing elements disposed within a plurality of pixel regions arranged in a pixel array of a first integrated chip (IC) tier. The plurality of pixel regions include a plurality of active pixel regions and one or more dummy pixel regions. A plurality of pixel support devices are disposed on a second substrate within a second IC tier that is bonded to the first IC tier. A plurality of logic devices are disposed within a third IC tier that is bonded to the second IC tier. A through substrate via (TSV) extends vertically through the second substrate laterally outside of the plurality of pixel support devices and directly below the pixel array.

### REFERENCE TO RELATED APPLICATIONS

This Application is a Continuation of U.S. application Ser. No. 18/401,771, filed on Jan. 2, 2024, which claims the benefit of U.S. Provisional Application No. 63/594,445, filed on Oct. 31, 2023. The contents of the above-referenced Patent Applications are hereby incorporated by reference in their entirety.

### BACKGROUND

Integrated circuits (IC) with image sensors are used in a wide range of modern-day electronic devices, such as cameras and cell phones, for example. In recent years, complementary metal-oxide semiconductor (CMOS) image sensors have begun to see widespread use, largely replacing charge-coupled device (CCD) image sensors. Compared to CCD image sensors, CMOS image sensors are increasingly favored due to low power consumption, a small size, fast data processing, a direct output of data, and low manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a multi-dimensional image sensor integrated chip (IC) structure comprising a through substrate via (TSV) located below a pixel array comprising a dummy pixel region.

FIG. 2 illustrates a top-view of some embodiments of a disclosed multi-dimensional image sensor IC structure comprising a TSV located below a pixel array comprising a dummy pixel region.

FIG. 3 illustrates a cross-sectional view of some additional embodiments of a disclosed multi-dimensional image sensor IC structure comprising a TSV located below a dummy pixel region within a pixel array.

FIGS. 4A-4B illustrate some additional embodiments of a disclosed multi-dimensional image sensor IC structure comprising a TSV located below a dummy pixel region within a pixel array.

FIGS. 5A-5B illustrate some additional embodiments of a disclosed multi-dimensional image sensor IC structure comprising a plurality of TSV located below a dummy pixel region within a pixel array.

FIGS. 6A-6B illustrate some additional embodiments of a disclosed multi-dimensional image sensor IC structure comprising a TSV located below a dummy pixel region within a pixel array.

FIGS. 7-8 illustrate top-views of some additional embodiments of disclosed multi-dimensional image sensor IC structures comprising a TSV located below a dummy pixel region within a pixel array.

FIG. 9 illustrates a cross-sectional view of some additional embodiments of a disclosed multi-dimensional image sensor IC structure comprising a TSV located below a pixel array comprising a dummy pixel region.

FIGS. 10-30 illustrate cross-sectional views of some embodiments of a method of forming a multi-dimensional image sensor IC structure comprising a TSV located below a pixel array comprising a dummy pixel region.

FIG. 31 illustrates a flow diagram of some embodiments of a method of forming a multi-dimensional image sensor IC structure comprising a TSV located below a pixel array comprising a dummy pixel region.

FIGS. 32-51 illustrate cross-sectional views of some additional embodiments of a method of forming a multi-dimensional image sensor IC structure comprising a TSV located below a pixel array comprising a dummy pixel region.

FIG. 52 illustrates a flow diagram of some additional embodiments of a method of forming a multi-dimensional image sensor IC structure comprising a TSV located below a pixel array comprising a dummy pixel region.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Image sensor integrated chip structures (e.g., complementary metal-oxide semiconductor sensors (CISs)) typically include a plurality of photodiodes arranged in pixel regions disposed in rows and columns of a pixel array. To improve a performance (e.g., resolution) of image sensor integrated chip structures, the semiconductor industry has increased a size of pixel arrays. In some embodiments, multi-dimensional image sensor integrated chip structures may comprise image sensing elements (e.g., photodiodes) disposed on a separate integrated chip tier than logic circuitry, so as to provide more size for a pixel array. For example, a multi-dimensional image sensor integrated chip structure may comprise a pixel array located on a first integrated chip tier, pixel support devices located below the pixel array on a second integrated chip tier, and image signal processing circuitry located on a third integrated chip tier.

In such multi-dimensional image sensor integrated chip structures, electrical connections between image signal processing circuitry and the pixel array and/or the pixel support devices can be achieved using through substrate vias (TSVs) extending through a substrate within one of the integrated chip tiers. To avoid damaging pixel support devices, the TSVs are typically located along a periphery of a pixel array. However, having the TSVs located along a periphery of the pixel array causes the multi-dimensional image sensor integrated chip structure to suffer from a relatively low transfer speed due to long electrical connection paths between the image signal processing circuitry and the pixel array and/or the pixel support devices. Furthermore, as the size of pixel arrays increases, the length of electrical connection paths increases, thereby increasing a parasitic resistance and decreasing a performance of the multi-dimensional image sensor integrated chip structure.

The present disclosure relates to a multi-dimensional image sensor integrated chip (IC) structure that has one or more through substrate vias (TSVs) arranged directly below a pixel array comprising one or more dummy pixel regions. In some embodiments, a disclosed multi-dimensional image sensor IC structure may comprise a first substrate, a second substrate, and a third substrate. A pixel array comprising a plurality of pixel regions is disposed within the first substrate, a plurality of pixel support devices are disposed on and/or within the second substrate, and a plurality of logic devices are disposed on and/or within the third substrate. The pixel array comprises a plurality of active pixel regions laterally surrounding one or more dummy pixel regions. The plurality of active pixel regions respectively comprise an image sensing element. A through substrate via (TSV) vertically extends through the second substrate at a location laterally outside of the plurality of pixel support devices, so as to provide an electrical connection between the plurality of pixel support devices and the plurality of logic devices. Because the dummy pixel region does not have associated pixel support devices, the dummy pixel region provides for a region within the second substrate that is free of pixel support devices and that is directly below the pixel array. The TSV can extend through the second substrate within the region, thereby allowing the TSV is able to provide for a shorter electrical connection path length between the plurality of pixel support devices and the plurality of logic devices. The shorter electrical connection path length provides for a lower resistance that improves a performance of the multi-dimensional image sensor IC structure.

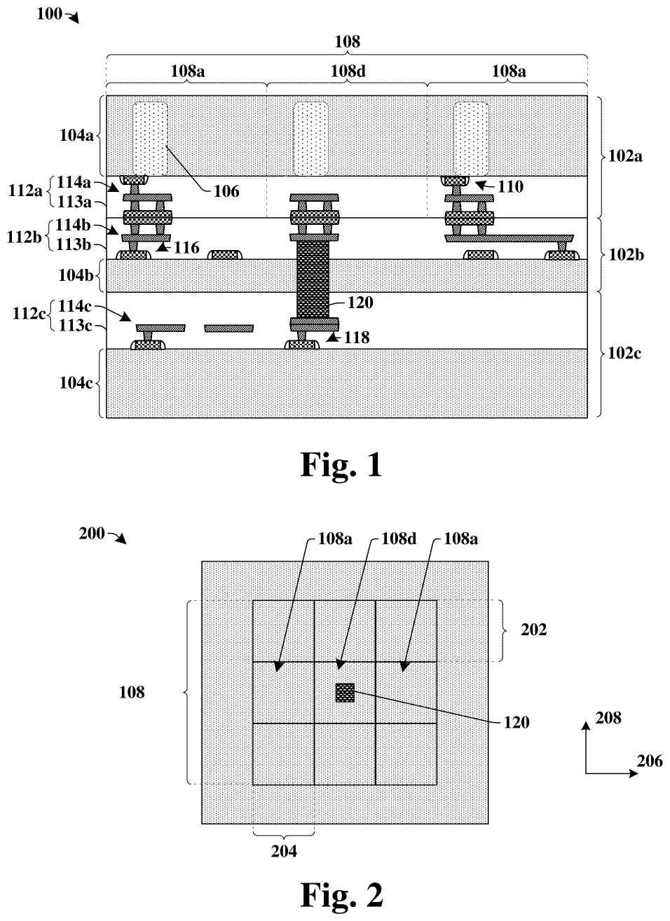

FIG. 1 illustrates a cross-sectional view of some embodiments of a disclosed multi-dimensional image sensor IC structure 100 comprising a through substrate via (TSV) located below a pixel array comprising a dummy pixel region.

The multi-dimensional image sensor IC structure 100 comprises a plurality of integrated chip (IC) tiers 102a-102c stacked onto one another. In some embodiments, the multi-dimensional image sensor IC structure 100 may comprise a three-dimensional integrated chip (3DIC) structure. In some embodiments, the plurality of IC tiers 102a-102c comprise a first IC tier 102a, a second IC tier 102b, and a third IC tier 102c.

The first IC tier 102a comprises a plurality of image sensing elements 106 disposed within a first substrate 104a. The plurality of image sensing elements 106 are disposed within a pixel array 108 comprising a plurality of pixel regions, 108a and 108d. A plurality of transfer gates 110 are disposed on and/or within the first substrate 104a. A first interconnect structure 112a is also disposed on the first substrate 104a. The first interconnect structure 112a comprises a first plurality of interconnects 114a disposed within a first inter-level dielectric (ILD) structure 113a. One or more of the first plurality of interconnects 114a are electrically coupled to the plurality of transfer gates 110.

The second IC tier 102b comprises a plurality of pixel support devices 116 disposed on and/or within a second substrate 104b. In some embodiments, the plurality of pixel support devices 116 may comprise a reset transistor, a source-follower transistor, a row-select transistor, and/or the like (e.g., transistors configured to operate as an analog-to-digital converter, an amplifier, a multiplexor, etc.). The plurality of pixel support devices 116 are connected to a second interconnect structure 112b comprising a second plurality of interconnects 114b disposed within a second ILD structure 113b. In various embodiments, the plurality of pixel support devices 116 may comprise a planar FET, a FinFET, a gate all around (GAA) transistor, a nanosheet transistor, and/or the like. In some embodiments, the first interconnect structure 112a is bonded to the second interconnect structure 112b along a bonding interface comprising one or more conductive interfaces and one or more dielectric interfaces.

The third IC tier 102c comprises a plurality of logic devices 118 disposed on and/or within a third substrate 104c. In some embodiments, the plurality of logic devices 118 may be configured to operate as image processing circuitry. In various embodiments, the plurality of logic devices 118 may comprise a planar FET, a FinFET, a gate all around FET (e.g., a nanosheet), and/or the like. A third interconnect structure 112c is disposed on the third substrate 104c. The third interconnect structure 112c comprises a third plurality of interconnects 114c disposed within a third ILD structure 113c. The third plurality of interconnects 114c are electrically coupled to the plurality of logic devices 118.

The plurality of pixel regions, 108a and 108d, comprise a plurality of active pixel regions 108a and one or more dummy pixel regions 108d. The one or more dummy pixel regions 108d are laterally surrounded by the plurality of active pixel regions 108a along a cross-sectional view. The plurality of active pixel regions 108a respectively comprise one or more of the plurality of image sensing elements 106 that are configured to generate a current that is provided to the plurality of pixel support devices 116 in response to incident radiation. The one or more dummy pixel regions 108d do not comprise an image sensing element that is configured to generate a current that is provided to the plurality of pixel support devices 116 in response to incident radiation, so that the one or more dummy pixel regions have no light-sensitive functionality. For example, in some embodiments the one or more dummy pixel regions 108d may respectively comprise one or more dummy image sensing elements of the plurality of image sensing elements 106, which are not electrically coupled to the plurality of pixel support devices 116

The plurality of pixel support devices 116 are disposed on and/or within the second substrate 104b directly below the pixel array 108. In some embodiments, the plurality of pixel support devices 116 are disposed on and/or within the second substrate 104b directly below the plurality of active pixel regions 108a and outside of the one or more dummy pixel regions 108d. In such embodiments, the second substrate 104b may be devoid of pixel support devices directly below the one or more dummy pixel regions 108d. In other embodiments, the plurality of pixel support devices 116 are disposed on and/or within the second substrate 104b directly below the one or more dummy pixel regions 108d and outside of one of the plurality of active pixel regions 108a. Because the one or more dummy pixel regions 108d do not have associated pixel support devices, the one or more dummy pixel regions 108d provide for one or more regions within the second substrate 104b that are laterally outside of pixel support devices 116 and that are directly below the pixel array 108.

A through-substrate-via (TSV) 120 extends through the second substrate 104b directly below the pixel array 108 and within the one or more regions that are laterally outside of the plurality of pixel support devices 116. The TSV 120 electrically connects the second plurality of interconnects 114b to the third plurality of interconnects 114c. In some embodiments, the TSV 120 may extend through the second substrate 104b directly below the one or more dummy pixel regions 108d. Because the one or more regions are located below the pixel array 108, the TSV 120 is able to provide for a relatively short electrical connection between the plurality of logic devices 118 and either plurality of image sensing elements 106 and/or the plurality of pixel support devices 116. The relatively short electrical connection reduces a parasitic resistance of the multi-dimensional image sensor IC structure 100 and improves a performance of the multi-dimensional image sensor IC structure 100.

FIG. 2 illustrates a top-view 200 of some embodiments of a disclosed multi-dimensional image sensor IC structure comprising a TSV located below a pixel array comprising a dummy pixel region.

As shown in top-view 200, a plurality of pixel regions, 108a and 108d, are arranged within a pixel array 108 having rows 202 and columns 204. The rows 202 extend in a first direction 206 and the columns 204 extend in a second direction 208 that is perpendicular to the first direction 206. The plurality of pixel regions, 108a and 108d, comprise a plurality of active pixel regions 108a and one or more dummy pixel regions 108d. The one or more dummy pixel regions 108d are laterally surrounded by the plurality of active pixel regions 108a in the first direction 206 and/or in the second direction 208.

During operation, image sensing elements within the plurality of active pixel regions 108a are configured to generate electrical signals in response to incident radiation. The electrical signals are provided to pixel support devices and/or logic devices disposed within substrates under the pixel array 108. The electrical signals may be provided between the pixel support devices and the logic devices by way of a TSV 120 that is directly below the pixel array 108 (e.g., that is laterally bounded by an outer perimeter of the pixel array 108). In some embodiments, the TSV 120 may be arranged directly below the one or more dummy pixel regions 108d within the pixel array 108. Because the TSV 120 is located directly below the pixel array 108, the TSV 120 is able to provide for a relatively short electrical connection between the plurality of logic devices and the plurality of pixel support devices.

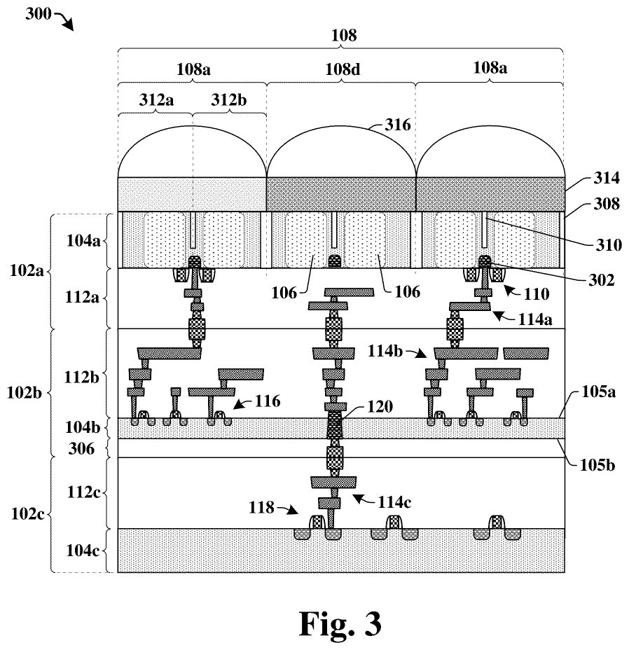

FIG. 3 illustrates some additional embodiments of a disclosed multi-dimensional image sensor IC structure 300 comprising a TSV located below a dummy pixel region within a pixel array.

The multi-dimensional image sensor IC structure 300 comprises a plurality of IC tiers 102a-102c stacked onto one another. In some embodiments, the plurality of IC tiers 102a-102c comprise a first IC tier 102a, a second IC tier 102b, and a third IC tier 102c. The first IC tier 102a comprises a plurality of image sensing elements 106 (e.g., photodetectors) disposed within a first substrate 104a. The plurality of image sensing elements 106 are disposed within a pixel array 108 comprising a plurality of active pixel regions 108a and one or more dummy pixel regions 108d. The plurality of active pixel regions 108a respectively comprise one or more of a plurality of transfer gates 110 arranged on the first substrate 104a. The plurality of transfer gates 110 are configured to selectively provide charges from the plurality of image sensing elements 106 to a floating diffusion region 302 disposed within the first substrate 104a. The floating diffusion region 302 is electrically coupled to one or more of the first plurality of interconnects 114a within a first interconnect structure 112a on the first substrate 104a. In some embodiments, the one or more dummy pixel regions 108d are devoid of a transfer gate, so that an image sensing element (e.g., a dummy image sensing element) within the one or more dummy pixel regions 108d is not electrically coupled to an interconnect within the first interconnect structure 112a.

In some embodiments, an isolation structure 308 is arranged within the first substrate 104a along opposing sides of the plurality of active pixel regions 108a and the one or more dummy pixel regions 108d. The isolation structure 308 may comprise one or more dielectric materials disposed within one or more trenches formed by sidewalls of the first substrate 104a. In some embodiments, the isolation structure 308 may comprise a back-side deep trench isolation (BS-DTI) structure comprising one or more dielectric materials disposed within one or more trenches extending into a back-side of the first substrate 104a. In some embodiments, the isolation structure 308 may extend completely through the first substrate 104a.

The second IC tier 102b comprises a plurality of pixel support devices 116 disposed on and/or within a front-side 105a of a second substrate 104b. In some embodiments, the plurality of pixel support devices 116 comprise a reset transistor, a source-follower transistor, and a row-select transistor. The reset transistor comprises a source coupled to the floating diffusion region 302. The source-follower transistor comprises a gate coupled to the floating diffusion region 302. The row-select transistor is coupled to a drain of the source-follower transistor. In some embodiments, the second IC tier 102b may further comprise one or more in-pixel devices (e.g., comprising column amplifiers and/or capacitors, column decoders, analog to digital converters, conversion gain transistors, voltage domain global shutter transistors, polysilicon capacitors, and/or the like) coupled to the plurality of pixel support devices 116. The plurality of pixel support devices 116 are coupled to one or more of the second plurality of interconnects 114b within a second interconnect structure 112b on the second substrate 104b. In some embodiments, the first interconnect structure 112a may comprise a first conductive bonding structure 304a that is bonded to a second conductive bonding structure 304b within the second interconnect structure 112b along an interface.

The third IC tier 102c comprises a plurality of logic devices 118 disposed on and/or within a front-side of a third substrate 104c and coupled to a third plurality of interconnects 114c within a third interconnect structure 112c. In some embodiments, the one or more logic devices 118 may be configured to perform operations such as image processing, analog data processing (e.g., noise reduction, data sampling, etc.), and/or the like. In some embodiments, the third interconnect structure 112c may comprise a third conductive bonding structure 304c disposed over the third plurality of interconnects 114c and along a top of the third interconnect structure 112c.

A TSV 120 vertically extends through the second substrate 104b at a location directly below one of the one or more dummy pixel regions 108d. The TSV 120 electrically couples the one or more pixel support devices 116 to the one or more logic devices 118. In some embodiments, the TSV 120 may extend from one of the second plurality of interconnects 114b to a back-side 105b of the second substrate 104b.

In some embodiments, the one or more dummy pixel regions 108d comprise one or more dummy image sensing elements of the plurality of image sensing elements 106. The one or more dummy image sensing elements are electrically isolated from the plurality of pixel support devices 116. The one or more dummy image sensing elements may improve process parameters (e.g., lithography parameters) during formation of the plurality of image sensing elements 106, thereby improving performance of the multi-dimensional image sensor IC structure 300. In some embodiments, the TSV 120 vertically extends through the second substrate 104b at a location directly below the one or more one or more dummy image sensing elements.

In some embodiments, the TSV 120 may comprise a back-side through-substrate via (BTSV) having tapered sidewalls that cause a width of the TSV 120 to decrease between the back-side 105b and the front-side 105a of the second substrate 104b. In some embodiments, the TSV 120 may physically contact an additional conductive bonding structure 304d disposed within an additional dielectric structure 306 arranged along the back-side 105b of the second substrate 104b. In some embodiments, the third conductive bonding structure 304c contacts the additional conductive bonding structure 304d along an interface.

During operation, electromagnetic radiation (e.g., photons) striking the plurality of image sensing elements 106 generates charge carriers, which are collected in the plurality of image sensing elements 106. When the plurality of transfer gates 110 are turned on, the charge carriers in the plurality of image sensing elements 106 within the plurality of active pixel regions 108a are transferred to the floating diffusion region 302 as a result of a potential difference existing between the plurality of image sensing elements 106 and the floating diffusion region 302. The charges are converted to voltage signals by the source-follower transistor and the row-select transistor is used for addressing. Prior to charge transfer, the floating diffusion region 302 may be set to a predetermined low charge state by turning on the reset transistor, which causes electrons in the floating diffusion region 302 to flow into a voltage source (V_{DD})).

In some embodiments, to enable auto focus functionality, the plurality of pixel regions, 108a and 108d, may respectively comprise two image sensor regions 312a-312b respectively including an image sensing element (e.g., photodiode) arranged in a dual-image sensing element configuration. During operation, a convex module lens (not shown) may be configured to focus incident radiation towards the multi-dimensional image sensor IC structure 300. If the incident radiation is in focus, the radiation will be evenly distributed between the image sensing elements within the two image sensor regions 312a-312b. However, if the incident radiation is out of focus, one of the image sensing elements will receive more radiation than the other. Accordingly, the amount of charge can be read independently from the image sensing elements and used to change a focus (e.g., a position) of the convex module lens.

In some embodiments, one or more additional isolation regions 310 may be disposed within the first substrate 104a over the floating diffusion region 302. In some such embodiments, the plurality of image sensor regions 312a-312b are separated from another by the one or more additional isolation regions 310. The one or more additional isolation regions 310 extend partially through the first substrate 104a, so as to provide electrical isolation between adjacent ones of the plurality of image sensor regions 312a-312b while still allowing for the floating diffusion region 302 to be shared between adjacent ones of the plurality of image sensor regions 312a-312b.

In some embodiments, a plurality of color filters 314 are disposed on a back-side of the first substrate 104a and a plurality of micro-lenses 316 are arranged on the plurality of color filters 314. The plurality of micro-lenses 316 respectively and directly overlie image sensing elements 106 within one of the plurality of pixel regions, 108a and 108d.

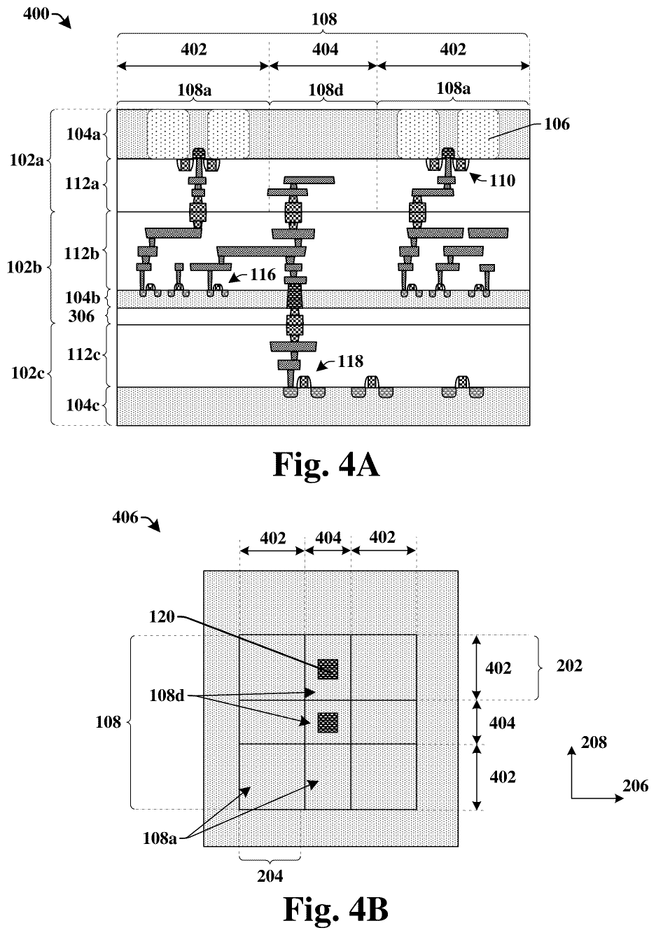

FIG. 4A illustrates a cross-sectional view of some additional embodiments of a disclosed multi-dimensional image sensor IC structure 400 comprising a TSV located below a dummy pixel region within a pixel array.

The multi-dimensional image sensor IC structure 400 comprises a plurality of IC tiers 102a-102c stacked onto one another. In some embodiments, the plurality of IC tiers 102a-102c comprise a first IC tier 102a, a second IC tier 102b, and a third IC tier 102c. The first IC tier 102a comprises a plurality of image sensing elements 106 (e.g., photodetectors) disposed within a first substrate 104a. The second IC tier 102b comprises a plurality of pixel support devices 116 disposed on and/or within a second substrate 104b. The third IC tier 102c comprises a plurality of logic devices 118 disposed on and/or within a third substrate 104c.

The plurality of image sensing elements 106 are disposed within a pixel array 108 comprising a plurality of active pixel regions 108a and one or more dummy pixel regions 108d. In some embodiments, the plurality of active pixel regions 108a may have a first width 402 and the one or more dummy pixel regions 108d may have a second width 404 that is different than the first width 402. In some embodiments, the first width 402 may be larger than the second width 404. In some embodiments, the first substrate 104a may be devoid of image sensing elements (e.g., photodiodes) within the dummy pixel region 108d.

FIG. 4B illustrates a top-view 406 of some embodiments corresponding to the multi-dimensional image sensor IC structure 400 of FIG. 4A. As shown in top-view 406, the plurality of active pixel regions 108a and the one or more dummy pixel regions 108d are arranged in the pixel array 108 in rows 202 and columns 204. In some embodiments, one or more of the plurality of active pixel regions 108a has a different shape than the one or more dummy pixel regions 108d. For example, one or more of the plurality of active pixel regions 108a has a square shape, while one or more of the dummy pixel regions 108d has a rectangular shape.

In some embodiments, at least one of the plurality of active pixel regions 108a has the first width 402 along a first direction 206 and along a second direction 208. In various embodiments, the one or more dummy pixel regions 108d may have the second width 404 along the first direction 206 and/or along the second direction 208. For example, in some embodiments the one or more dummy pixel regions 108d may have the second width 404 along both the first direction 206 and the second direction 208. In other embodiments, the one or more dummy pixel regions 108d may have either the first width 402 along the first direction 206 and the second width 404 along the second direction 208 or the second width 404 along the first direction 206 and the first width 402 along the second direction 208.

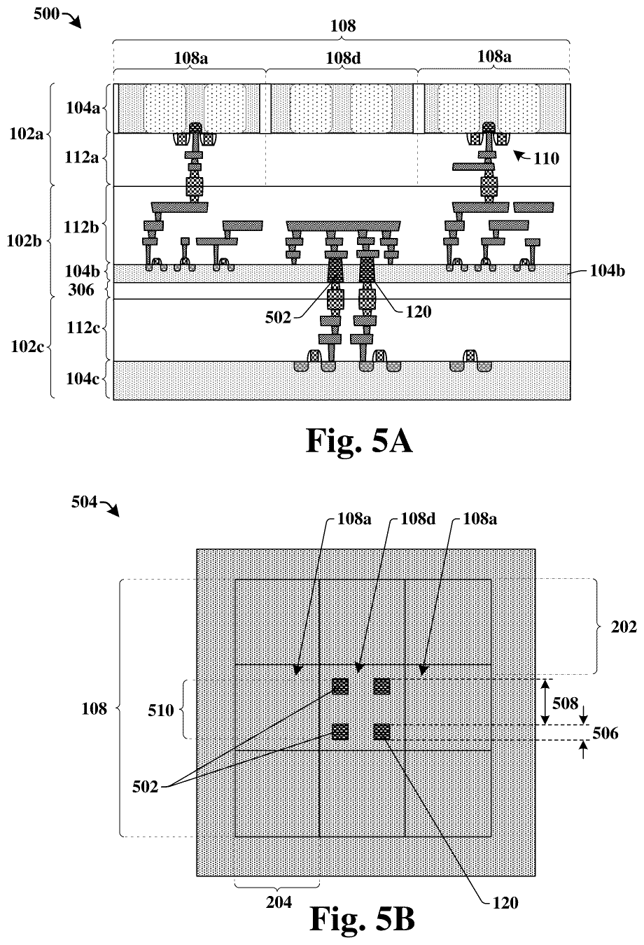

FIG. 5A illustrates a cross-sectional view of some additional embodiments of a disclosed multi-dimensional image sensor IC structure 500 comprising a TSV located below a dummy pixel region within a pixel array.

The multi-dimensional image sensor IC structure 500 comprises a first IC tier 102a, a second IC tier 102b stacked onto the first IC tier 102a, and a third IC tier 102c stacked onto the second IC tier 102b. The first IC tier 102a comprises a pixel array 108 comprising a plurality of active pixel regions 108a and one or more dummy pixel regions 108d. The plurality of active pixel regions 108a respectively comprise one or more of a plurality of transfer gates 110 arranged on the first substrate 104a.

The first IC tier 102a further comprises a first interconnect structure 112a arranged on a first substrate 104a. In some embodiments, the first interconnect structure 112a is devoid of interconnects below the one or more dummy pixel regions 108d. The second IC tier 102b comprises a second interconnect structure 112b arranged on a second substrate 104b. The third IC tier 102c comprises a third interconnect structure 112c arranged on a third substrate 104c.

A TSV 120 extends through the second substrate 104b directly below the one or more dummy pixel regions 108d. One or more additional TSVs 502 also extend through the second substrate 104b directly below the one or more dummy pixel regions 108d. The TSV 120 is laterally separated from the one or more additional TSVs 502 by the second substrate 104b. The TSV 120 and the one or more additional TSVs 502 are arranged between adjacent ones of the plurality of active pixel regions 108a along a cross-sectional view.

FIG. 5B illustrates a top-view 504 of some embodiments corresponding to the multi-dimensional image sensor IC structure 500 of FIG. 5A. As shown in top-view 504, both the TSV 120 and the one or more additional TSVs 502 are arranged in a same dummy pixel region of the one or more dummy pixel regions 108d and are separated from one another along a first direction 206 and/or a second direction 208. In some embodiments, the TSV 120 and the one or more additional TSVs 502 are arranged within the same dummy pixel region in a TSV array 510. In some embodiments, the TSV array 510 may comprise a 2×2 array, a 3×3 array, etc.

In some embodiments, the TSV 120 and the one or more additional TSVs 502 may respectively have a width 506 and a pitch 508. In some embodiments, the width 506 may be in a range of between approximately 1.5 microns (μm) and approximately 0.2 μm, between approximately 0.5 μm and approximately 0.2 μm, approximately 0.3 μm, or other similar values. In some embodiments, the pitch 508 may be in a range of between approximately 0.5 microns (μm) and approximately 2.5 μm, between approximately 0.8 μm and approximately 1.2 μm, approximately 1 μm, or other similar values.

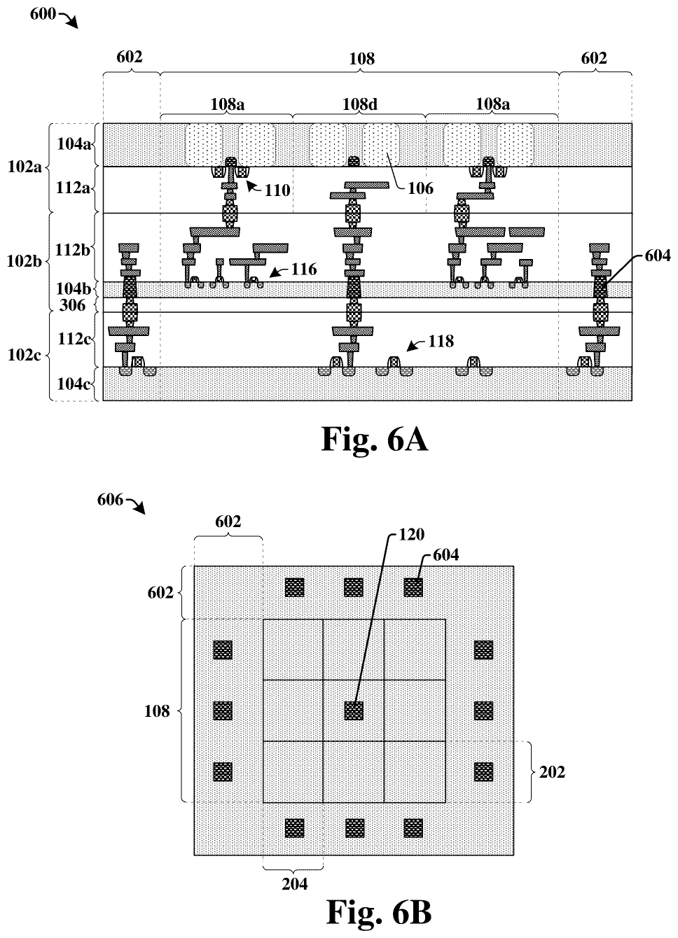

FIGS. 6A-6B illustrate some additional embodiments of a disclosed multi-dimensional image sensor IC structure comprising a TSV located below a dummy pixel region within a pixel array.

The multi-dimensional image sensor IC structure 600 comprises a first IC tier 102a, a second IC tier 102b stacked onto the first IC tier 102a, and a third IC tier 102c stacked onto the second IC tier 102b. The first IC tier 102a comprises a plurality of image sensing elements 106 (e.g., photodetectors) disposed within a first substrate 104a. The plurality of image sensing elements 106 are disposed within a pixel array 108 comprising a plurality of active pixel regions 108a and one or more dummy pixel regions 108d. The plurality of active pixel regions 108a respectively comprise one or more of a plurality of transfer gates 110 arranged on the first substrate 104a.

A peripheral region 602 surrounds the pixel array 108. One or more peripheral TSVs 604 are arranged within the peripheral region 602 and laterally outside of the pixel array 108. The one or more peripheral TSVs 604 vertically extend through the second substrate 104b to provide for additional electrical connections between the second IC tier 102b and the third IC tier 102c (e.g., between a plurality of pixel support devices 116 and a plurality of logic devices 118). As show in top-view 606 of FIG. 6B, the peripheral region 602 extends around an outer perimeter of the pixel array 108.

By having both a TSV 120 and one or more peripheral TSVs 604 provide electrical connections between the second IC tier 102b and the third IC tier 102c, a shorter electrical connection can be achieved between the plurality of logic devices 118 and either plurality of image sensing elements 106 and/or the plurality of pixel support devices 116. The shorter electrical connection provides for a lower resistance that improves a performance of the multi-dimensional image sensor IC structure 600.

FIG. 7 illustrates a top-view of some additional embodiments of a disclosed multi-dimensional image sensor IC structure 700 comprising a TSV located below a dummy pixel region within a pixel array.

The multi-dimensional image sensor IC structure 700 comprises a pixel array 108 having a plurality of active pixel regions 108a and one or more dummy pixel regions 108d. In some embodiments, the one or more dummy pixel regions 108d may comprise at least two dummy pixels regions. The at least two dummy pixels regions may be disposed in different rows 202 and/or different columns 204. In some embodiments, the at least two dummy pixel regions may be separated along a first direction 206 and along a second direction 208. In some embodiments, the at least two dummy pixels regions may be arranged in a periodic pattern within the pixel array 108. In some embodiments, the at least two dummy pixel regions may comprise between approximately 6 dummy pixel regions and approximately 600 dummy pixel regions within the pixel array 108.

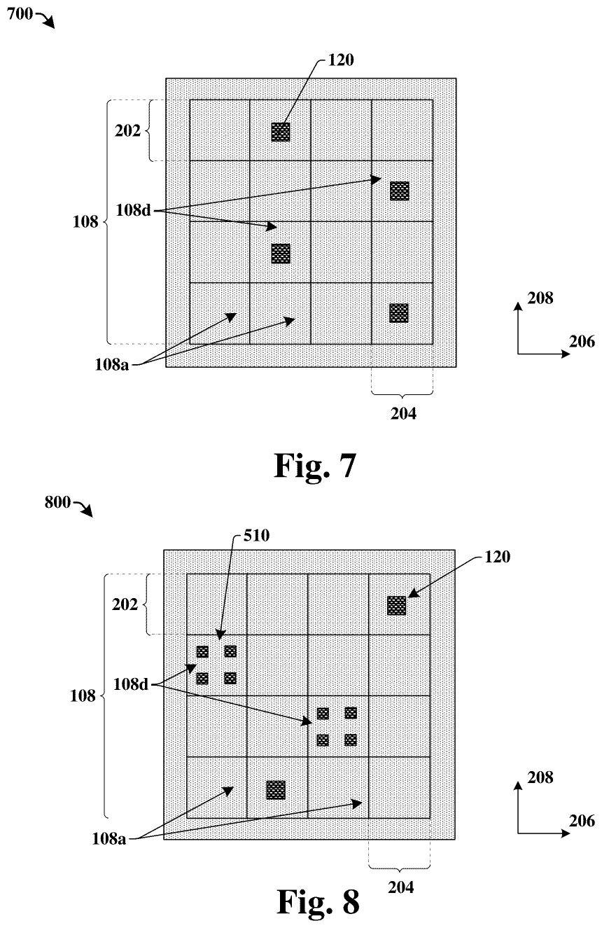

FIG. 8 illustrates a top-view of some additional embodiments of a disclosed multi-dimensional image sensor IC structure 800 comprising a TSV located below a dummy pixel region within a pixel array.

The multi-dimensional image sensor IC structure 800 comprises a pixel array 108 having a plurality of active pixel regions 108a and one or more dummy pixel regions 108d. In some embodiments, the one or more dummy pixel regions 108d may comprise at least two dummy pixels regions. The at least two dummy pixels regions may be disposed in different rows 202 and/or different columns 204. In some embodiments, the at least two dummy pixel regions may be separated along a first direction 206 and along a second direction 208. In some embodiments, the at least two dummy pixels regions may respectively comprise a TSV array 510, so that a plurality TSV arrays are arranged below the pixel array 108. In some additional embodiments, the at least two dummy pixel regions may respectively comprise a TSV 120. In yet other embodiments, at least one of the dummy pixel regions may comprise a TSV 120 and at least one of the dummy pixel regions may comprise a TSV array 510.

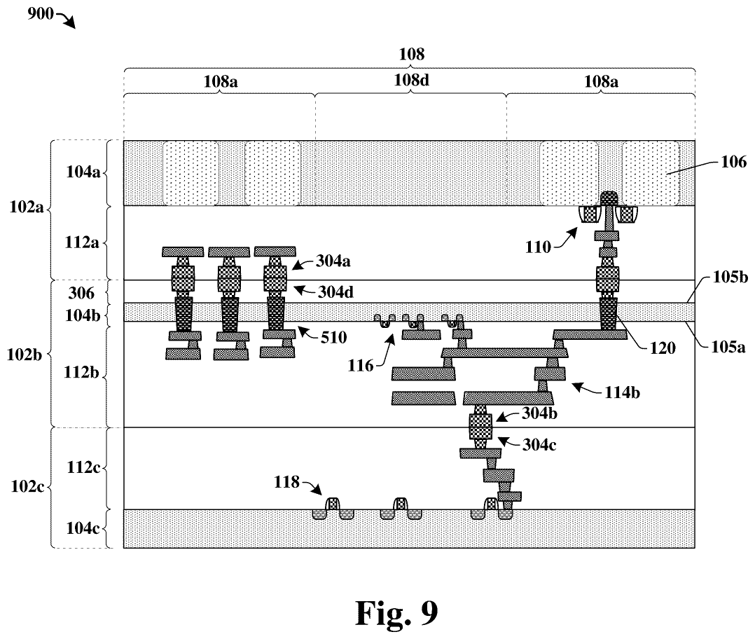

FIG. 9 illustrates a cross-sectional view of some additional embodiments of a disclosed multi-dimensional image sensor IC structure 900 comprising a TSV located below a pixel array comprising a dummy pixel region.

The multi-dimensional image sensor IC structure 900 comprises a plurality of IC tiers 102a-102c stacked onto one another. In some embodiments, the plurality of IC tiers 102a-102c comprise a first IC tier 102a, a second IC tier 102b, and a third IC tier 102c. The first IC tier 102a comprises a plurality of image sensing elements 106 (e.g., photodetectors) disposed within a first substrate 104a. A first interconnect structure 112a is disposed on a front-side of the first substrate 104a. The second IC tier 102b comprises a plurality of pixel support devices 116. A second interconnect structure 112b is disposed on a front-side 105a of the second substrate 104b and an additional conductive bonding structure 304d is disposed within an additional dielectric structure 306 on a back-side 105b of the second substrate 104b. The third IC tier 102c comprises a plurality of logic devices 118 disposed on and/or within a front-side of a third substrate 104c. A third interconnect structure 112c is disposed on the front-side of the third substrate 104c. The front-side of the first substrate 104a is bonded to the back-side 105b of the second substrate 104b. The front-side 105a of the second substrate 104b is bonded to the front-side of the third substrate 104c.

The plurality of image sensing elements 106 are disposed within a pixel array 108 comprising a plurality of active pixel regions 108a and one or more dummy pixel regions 108d. The plurality of active pixel regions 108a respectively comprise one or more of the plurality of image sensing elements 106 that are configured to generate a current that is provided to the plurality of pixel support devices 116 in response to incident radiation. The one or more dummy pixel regions 108d do not comprise an image sensing element that is configured to generate a current that is provided to the plurality of pixel support devices in response to incident radiation so that the one or more dummy pixel regions have no light-sensitive functionality.

A plurality of pixel support devices 116 are arranged within the second substrate 104b directly below the dummy pixel region 108d. The plurality of image sensing elements 106 within the plurality of active pixel regions 108a are electrically coupled to the plurality of pixel support devices 116 by way of a TSV 120 extending through the second substrate 104b laterally outside of the pixel support devices 116. For example, in some embodiments the TSV 120 extends through the second substrate 104b directly below one of the plurality of active pixel regions 108a to connect to the second plurality of interconnects 114b, which are electrically coupled to the plurality of pixel support devices 116. In some additional embodiments, a TSV array 510 may extend through the second substrate 104b laterally outside of the plurality of pixel support devices 116. For example, in some embodiments the TSV array 510 may extend through the second substrate 104b directly below one of the plurality of active pixel regions 108a to connect to the second plurality of interconnects 114b.

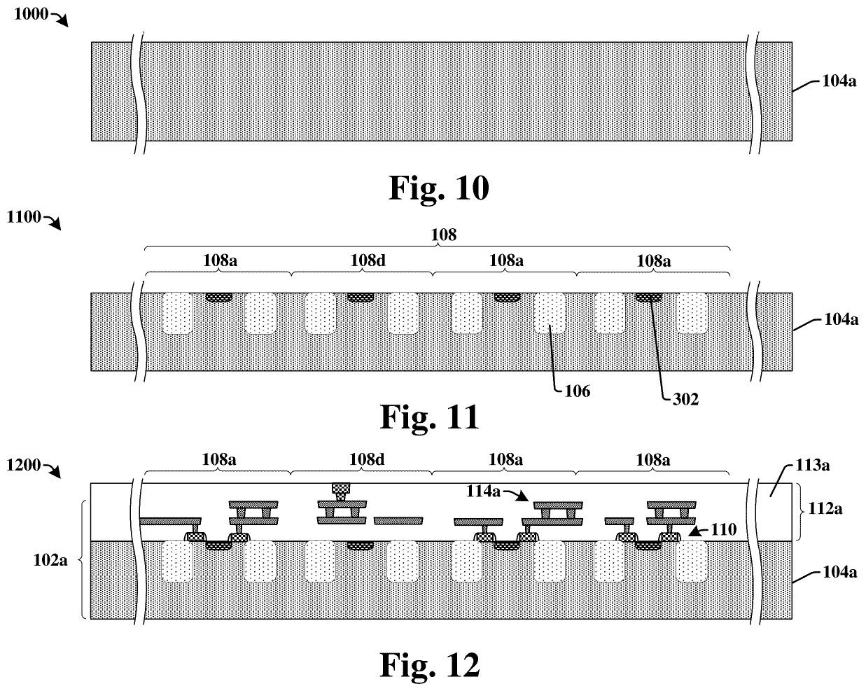

FIGS. 10-30 illustrate cross-sectional views of some embodiments of a method of forming a multi-dimensional image sensor IC structure comprising a TSV located below a pixel array comprising a dummy pixel region. Although FIGS. 10-30 are described in relation to a method, it will be appreciated that the structures disclosed in the method are not limited to the method, but instead may stand alone as structures independent of the method.

As shown in cross-sectional view 1000 of FIG. 10, a first substrate 104a is provided. In various embodiments, the first substrate 104a may be any type of semiconductor body (e.g., silicon, SiGe, etc.), such as a semiconductor wafer and/or one or more die on a wafer, as well as any other type of semiconductor and/or epitaxial layers, associated therewith.

As shown in cross-sectional view 1100 of FIG. 11, a plurality of image sensing elements 106 are formed within a plurality of pixel regions, 108a and 108d, in a pixel array 108 within the first substrate 104a. In some embodiments, the plurality of pixel regions, 108a and 108d, may comprise a plurality of active pixel regions 108a and one or more dummy pixel regions 108d.

In some embodiments, the plurality of image sensing elements 106 may comprise a photodiode formed by implanting one or more dopant species into a front-side of the first substrate 104a. For example, the plurality of image sensing elements 106 may be formed by selectively performing a first implantation process (e.g., according to a first masking layer) to form a first region having a first doping type (e.g., n-type), and subsequently performing a second implantation process to form a second region abutting the first region and having a second doping type (e.g., p-type) different than the first doping type. In some embodiments a floating diffusion region 302 may also be formed within the first substrate 104a. The floating diffusion region 302 may be formed by selectively implanting one or more dopants into the first substrate 104a according to a masking layer. In some embodiments, the floating diffusion region 302 may be formed using one of the first or second implantation processes.

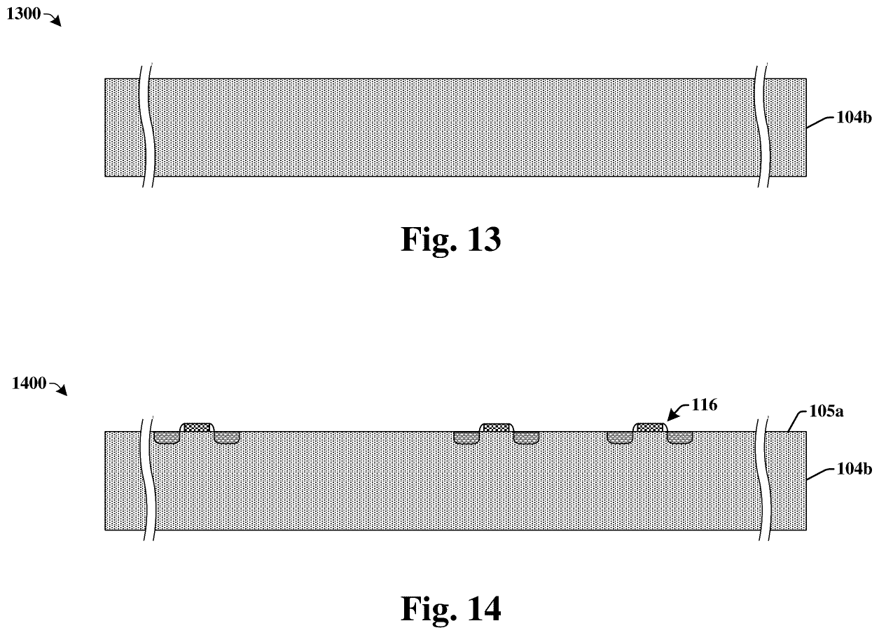

As shown in cross-sectional view 1200 of FIG. 12, a plurality of transfer gates 110 are formed along the front-side of the first substrate 104a and within the plurality of active pixel regions 108a. In some embodiments, the plurality of transfer gates 110 may be formed by depositing a gate dielectric film and a gate electrode film on the front-side of the first substrate 104a. The gate dielectric film and the gate electrode film are subsequently patterned to form a gate dielectric layer and a gate electrode. Sidewall spacers may be formed on the outer sidewalls of the gate electrode. In some embodiments, the sidewall spacers may be formed by depositing a spacer layer (e.g., a nitride, an oxide, etc.) onto the front-side of the first substrate 104a and selectively etching the spacer layer to form the sidewall spacers.

A first interconnect structure 112a is formed onto the front-side of the first substrate 104a. The first interconnect structure 112a comprises a first plurality of interconnects 114a formed within a first ILD structure 113a comprising one or more ILD layers. The first plurality of interconnects 114a include conductive contacts, interconnects wires, and/or interconnect vias. In some embodiments, the first interconnect structure 112a may be formed using a damascene process (e.g., a single damascene process and/or a dual damascene process). For example, the damascene process may be performed by forming an ILD layer over the front-side of the first substrate 104a, etching the ILD layer to form a via hole and/or a trench, filling the via hole and/or trench with a conductive material, and performing a planarization process (e.g., a chemical mechanical planarization process) to remove excess of the conductive material from over the ILD layer. In some embodiments, the ILD layer may be deposited by a physical vapor deposition technique (e.g., PVD, CVD, PE-CVD, ALD, etc.) and the conductive material may be formed using a deposition process and/or a plating process (e.g., electroplating, electro-less plating, etc.). In various embodiments, the conductive material may comprise tungsten, copper, aluminum, copper, and/or the like.

As shown in cross-sectional view 1300 of FIG. 13, a second substrate 104b is provided. In various embodiments, the second substrate 104b may be any type of semiconductor body (e.g., silicon, SiGe, etc.), such as a semiconductor wafer and/or one or more die on a wafer, as well as any other type of semiconductor and/or epitaxial layers, associated therewith.

As shown in cross-sectional view 1400 of FIG. 14, a plurality of pixel support devices 116 are formed on and/or within a front-side 105a of the second substrate 104b. In some embodiments, the plurality of pixel support devices 116 may comprise a reset transistor, a source-follower transistor, a row-select transistor, and/or the like. In some embodiments, the plurality of pixel support devices 116 may be formed by depositing a gate dielectric film and a gate electrode film over the second substrate 104b. The gate dielectric film and the gate electrode film are subsequently patterned to form a gate dielectric and a gate electrode. The second substrate 104b may be subsequently implanted to form source/drain regions within the second substrate 104b and on opposing sides of the gate electrode.

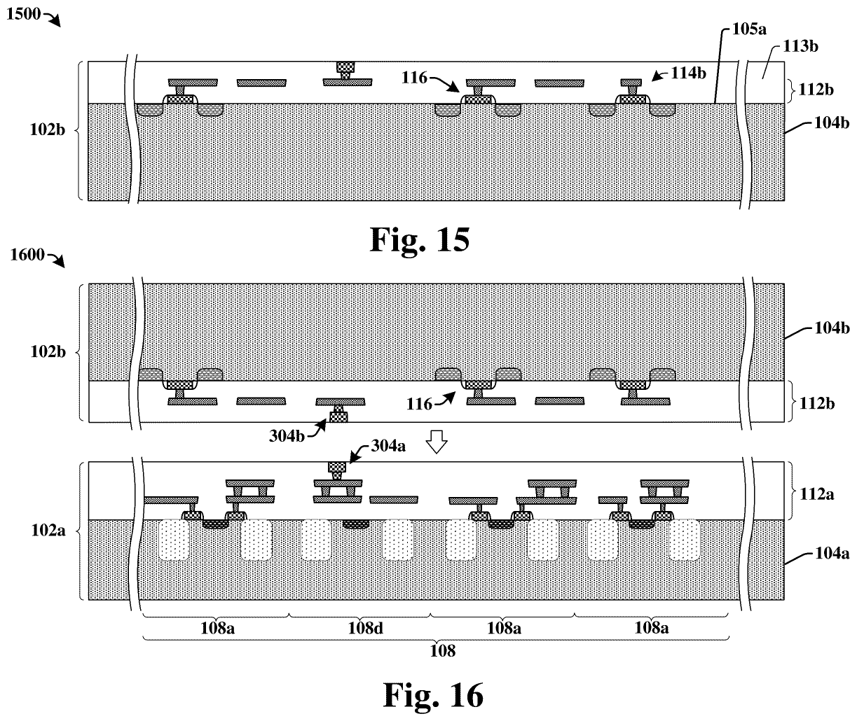

As shown in cross-sectional view 1500 of FIG. 15, a second interconnect structure 112b is formed onto the front-side 105a of the second substrate 104b. The second interconnect structure 112b comprises a second plurality of interconnects 114b formed within a second ILD structure 113b comprising one or more ILD layers. In some embodiments, the second interconnect structure 112b may be formed using a damascene process (e.g., a single damascene process and/or a dual damascene process).

As shown in cross-sectional view 1600 of FIG. 16, the second substrate 104b is bonded to the first substrate 104a so that one or more regions of the second substrate 104b are laterally outside of the pixel support devices 116 and vertically below the pixel array 108. In various embodiments, the second substrate 104b may be bonded to the first substrate 104a by way of a bonding process that forms a bonding interface comprising a dielectric interface and a metal interface. In some embodiments, the first substrate 104a may be bonded to the second substrate 104b along a bonding interface comprising a first conductive bonding structure 304a and a second conductive bonding structure 304b.

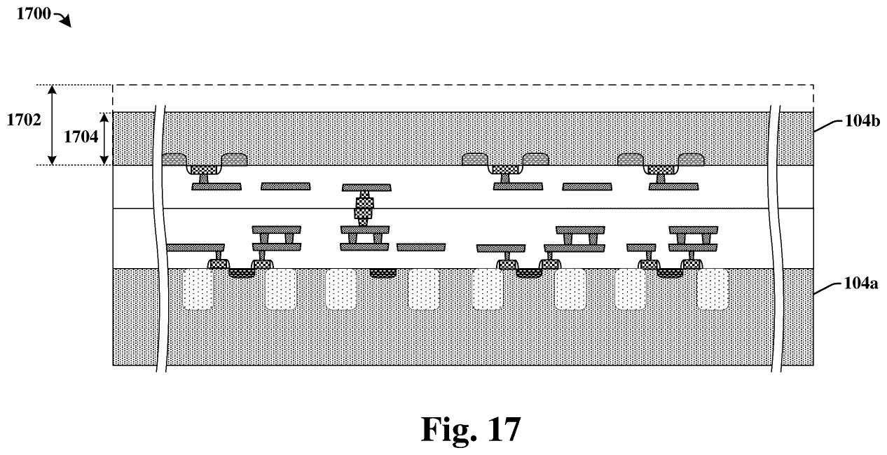

As shown in cross-sectional view 1700 of FIG. 17, a thickness of the second substrate 104b is reduced. In some embodiments, the thickness of the second substrate 104b may be reduced by performing a first grinding process on the second substrate 104b to reduce the thickness of the second substrate 104b from a first thickness 1702 to a second thickness 1704 that is less than the first thickness 1702. In some embodiments, the first thickness 1702 may be in a first range of between approximately 595 μm and approximately 950 μm, between approximately 700 μm and 800 μm, or other suitable values. In some embodiments, the second thickness 1704 may be in a second range of between approximately 0.5 μm and approximately 10 μm, between approximately 1 μm and approximately 8 μm, or other similar values.

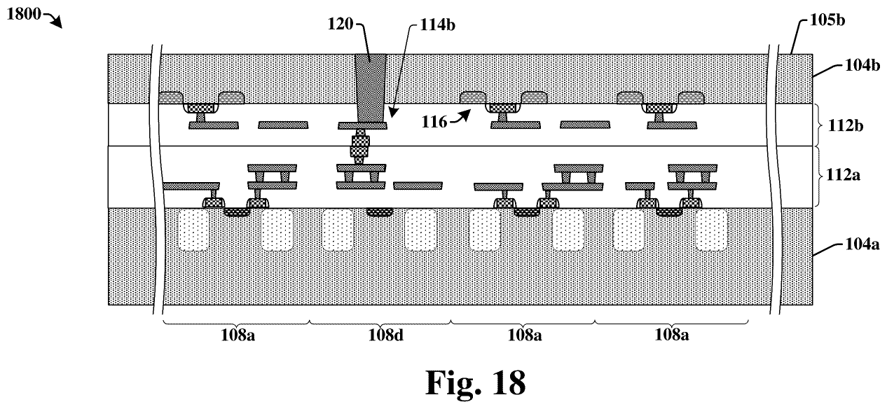

As shown in cross-sectional view 1800 of FIG. 18, a through-substrate-via (TSV) 120 is formed to extend through the second substrate 104b within the one or more regions that are laterally outside of the pixel support devices 116. The TSV 120 is formed by performing an etching process to selectively etch through the second substrate 104b and/or the second interconnect structure 112b to form a TSV opening. In some embodiments, the etching process may expose a back-side 105b of the second substrate 104b to an etchant. A conductive material is subsequently formed within the TSV opening followed by a planarization process (e.g., a CMP process).

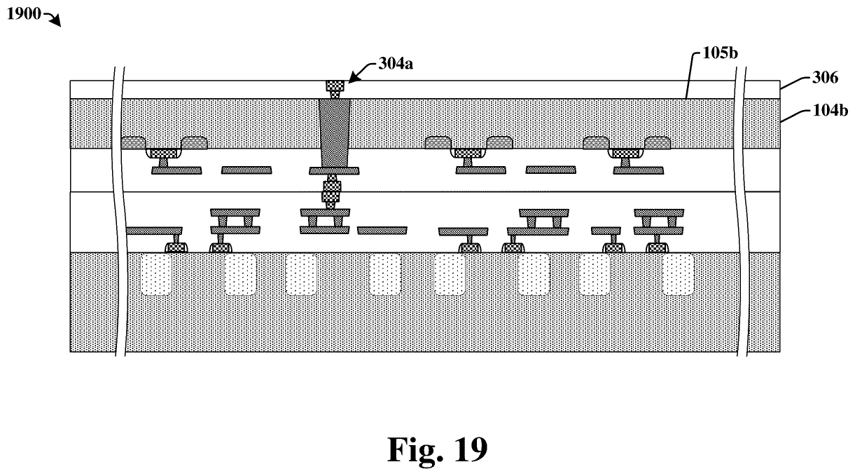

As shown in cross-sectional view 1900 of FIG. 19, an additional conductive bonding structure 304d is formed within an additional dielectric structure 306 formed onto the back-side 105b of the second substrate 104b.

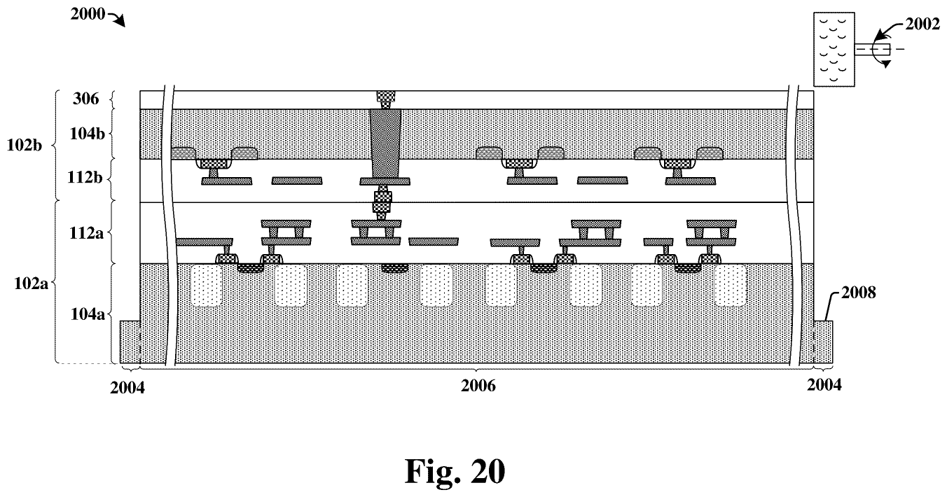

As shown in cross-sectional view 2000 of FIG. 20, a first edge trimming cut is performed on the first substrate 104a and the second substrate 104b. The first edge trimming cut removes peripheral portions 2004 of the first substrate 104a and the second substrate 104b that surround a central portion 2006 of the first substrate 104a and the second substrate 104b. In some embodiments, the first edge trimming cut forms a recessed upper surface 2008 within the first substrate 104a. In some embodiments, the first edge trimming cut may be performed by bringing a first blade 2002 into contact with the second substrate 104b along a closed loop. The first blade 2002 has abrasive elements (e.g., diamond particles) bonded to a core having a circular cross-section. The core is configured to rotate around a first axis, as the abrasive elements are brought into contact with the second substrate 104b.

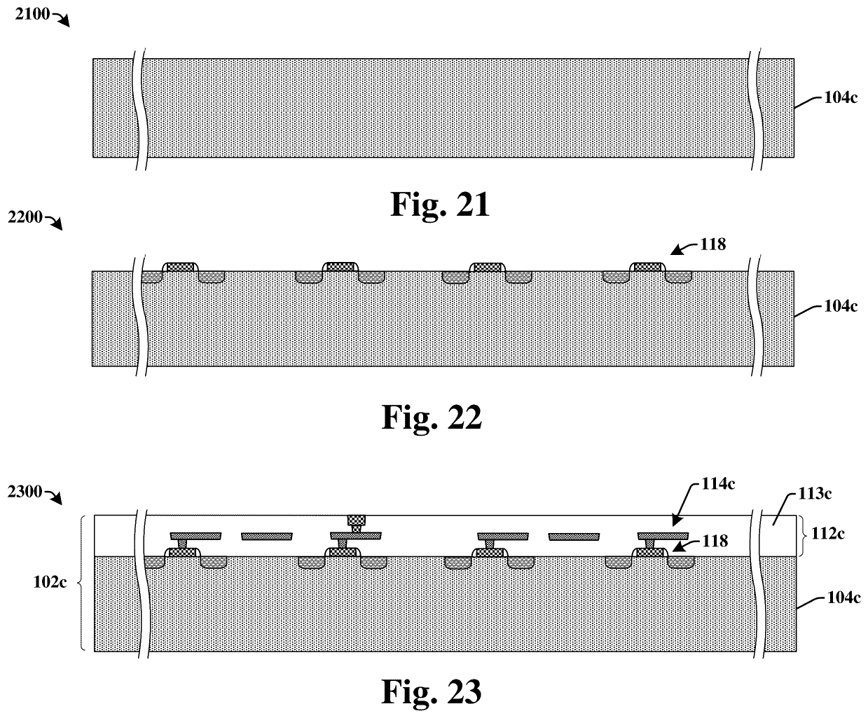

As shown in cross-sectional view 2100 of FIG. 21, a third substrate 104c is provided. In various embodiments, the third substrate 104c may be any type of semiconductor body (e.g., silicon, SiGe, etc.), such as a semiconductor wafer and/or one or more die on a wafer, as well as any other type of semiconductor and/or epitaxial layers, associated therewith.

As shown in cross-sectional view 2200 of FIG. 22, a plurality of logic devices 118 are formed on and/or within the third substrate 104c. In some embodiments, the plurality of logic devices 118 may comprise a transistor formed by depositing a gate dielectric film and a gate electrode film over the third substrate 104c. The gate dielectric film and the gate electrode film are subsequently patterned to form a gate dielectric and a gate electrode. The third substrate 104c may be subsequently implanted to form source/drain regions within the third substrate 104c and on opposing sides of the gate electrode.

As shown in cross-sectional view 2300 of FIG. 23, a third interconnect structure 112c is formed onto a front-side of the third substrate 104c. The third interconnect structure 112c comprises a third plurality of interconnects 114c formed within a third ILD structure 113c comprising one or more ILD layers. In some embodiments, the third interconnect structure 112c may be formed using a damascene process (e.g., a single damascene process and/or a dual damascene process).

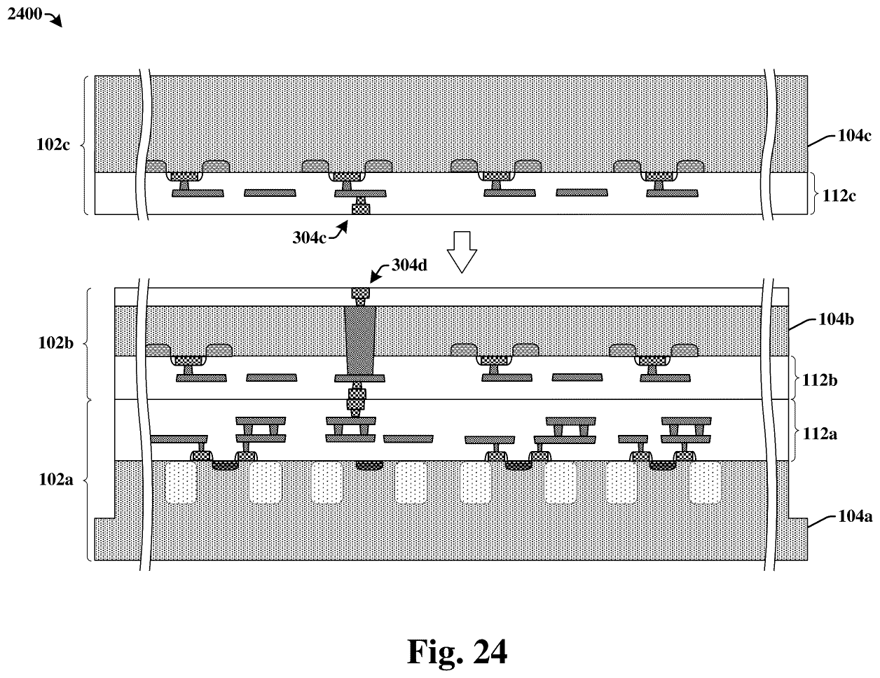

As shown in cross-sectional view 2400 of FIG. 24, the second substrate 104b is bonded to the third substrate 104c to form a semiconductor structure. In various embodiments, the second substrate 104b may be bonded to the third substrate 104c by way of a bonding process that forms a bonding interface comprising a dielectric interface and a metal interface. In some embodiments, the second substrate 104b is bonded to the third substrate 104c along a bonding interface comprising a third conductive bonding structure 304c and the additional conductive bonding structure 304d.

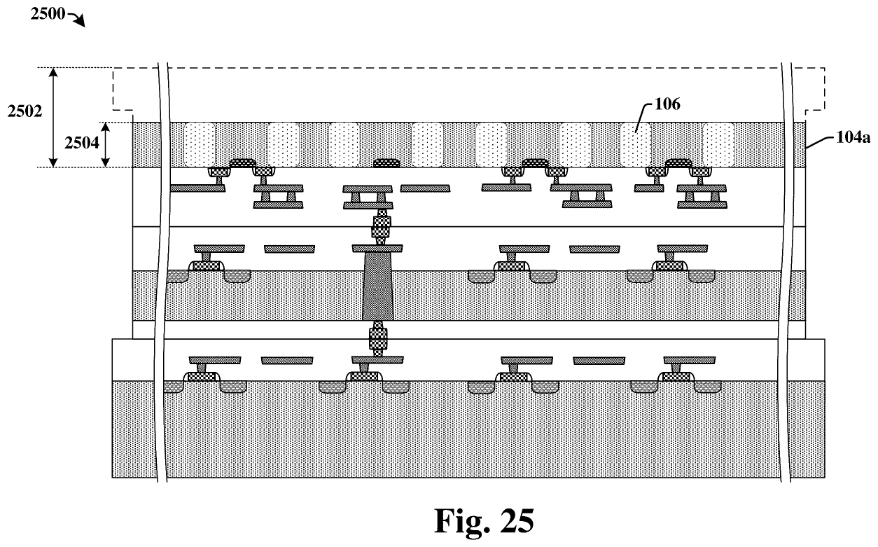

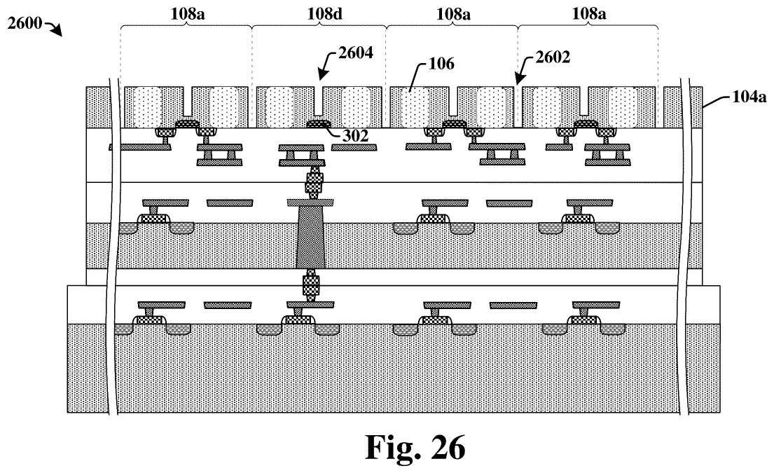

As shown in cross-sectional view 2500 of FIG. 25, a thickness of the first substrate 104a is reduced. In some embodiments, the thickness of the first substrate 104a may be reduced by performing a second grinding process on the first substrate 104a to reduce the thickness of the first substrate 104a from a first thickness 2502 to a second thickness 2504 that is less than the first thickness 2502. Thinning the first substrate 104a allows for radiation to pass more easily to the plurality of image sensing elements 106. In various embodiments, the first substrate 104a may be thinned by etching and/or mechanical grinding a back-side of the first substrate 104a.

As shown in cross-sectional view 2600 of FIG. 26, one or more trenches 2602 are formed within the back-side of the first substrate 104a. The one or more trenches 2602 vertically extend from the back-side of the first substrate 104a to within the first substrate 104a along opposing sides of the plurality of pixel regions, 108a and 108d. In some embodiments, the one or more trenches 2602 may be formed by selectively etching the back-side of the first substrate 104a with a first etching process. In some embodiments, the back-side of the first substrate 104a may be selectively etched by exposing the back-side of the first substrate 104a to one or more etchants according to a first masking layer. In some embodiments, the masking layer may comprise a photoresist, a hard mask, or the like. In some embodiments, the one or more etchants may comprise a dry etchant. In some embodiments, the dry etchant may have an etching chemistry comprising one or more of oxygen (O₂), nitrogen (N₂), hydrogen (H₂), argon (Ar), and/or a fluorine species (e.g., CF₄, CHF₃, C₄F₈, etc.).

In some additional embodiments, the one or more additional trenches 2604 may be formed by selectively etching the back-side of the first substrate 104a with a second etching process. In some embodiments, the back-side of the first substrate 104a may be selectively etched by exposing the back-side of the first substrate 104a to one or more etchants according to a second masking layer. The one or more additional trenches 2604 may extend into the first substrate 104a to a lesser depth than the one or more trenches 2602. In other additional embodiments (not shown), an isolation implantation process may be performed to form an isolation implantation region within the first substrate 104a.

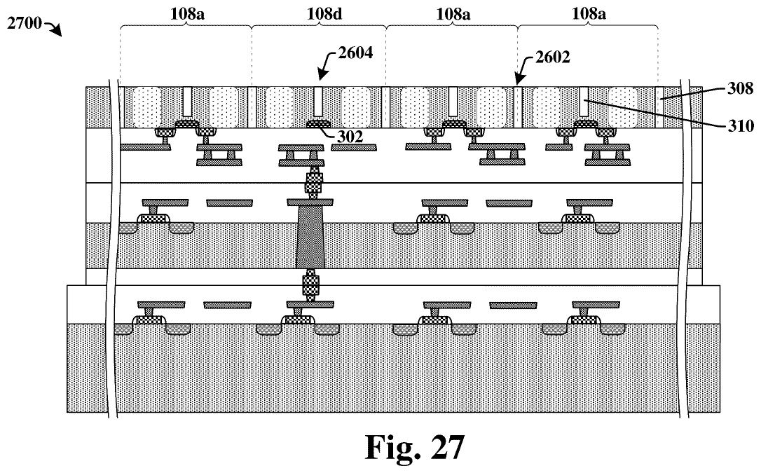

As shown in cross-sectional view 2700 of FIG. 27, one or more dielectric materials are formed within the one or more trenches 2602 to form an isolation structure 308 on opposing sides of the plurality of pixel regions, 108a and 108d. In some embodiments, the one or more dielectric materials may be formed to line interior surface of the first substrate 104a forming the one or more trenches 2602 and to further cover the back-side of the first substrate 104a. In some such embodiments, after forming the one or more dielectric materials, a planarization process (e.g., a chemical mechanical planarization (CMP) process) may be performed to remove the one or more dielectric materials from the back-side of the first substrate 104a. In some embodiments, the one or more dielectric materials may be formed by way of a vapor deposition process (e.g., a chemical vapor deposition (CVD) process, a plasma enhanced CVD process, or the like). In other embodiments, the one or more dielectric materials may be formed by way of an atomic layer deposition (ALD) process. The one or more dielectric materials may also be formed within the one or more additional trenches 2604 to form one or more additional isolation regions 310.

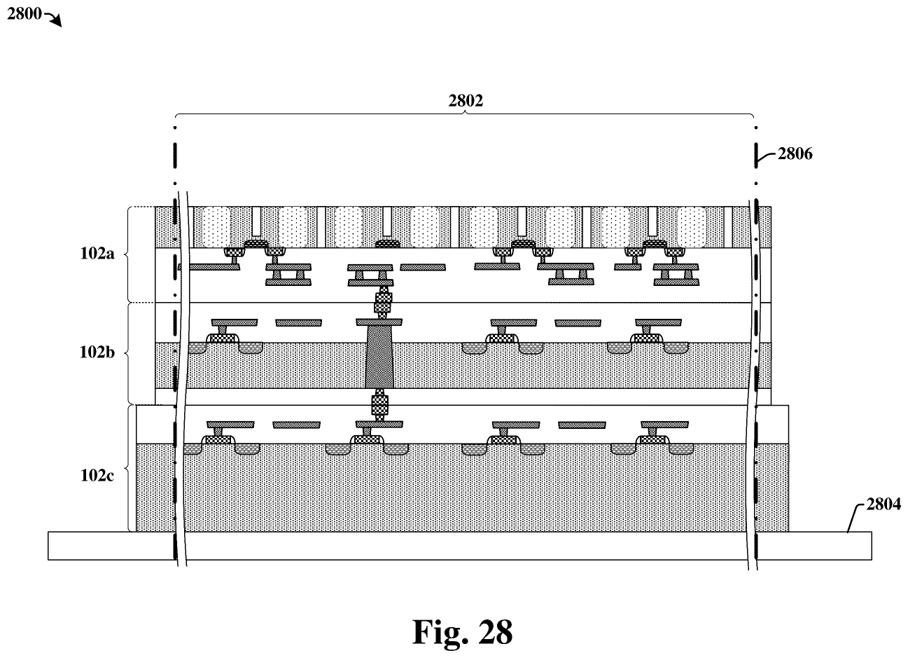

As shown in cross-sectional view 2800 of FIG. 28, the semiconductor structure is singulated to form one or more integrated chip die 2802. In some embodiments, the semiconductor structure may be singulated by a dicing process that mounts the semiconductor structure onto a sticky surface of a piece of dicing tape 2804. A wafer saw then cuts the wafer along scribe lines 2806 to separate the wafer into the one or more integrated chip die 2802.

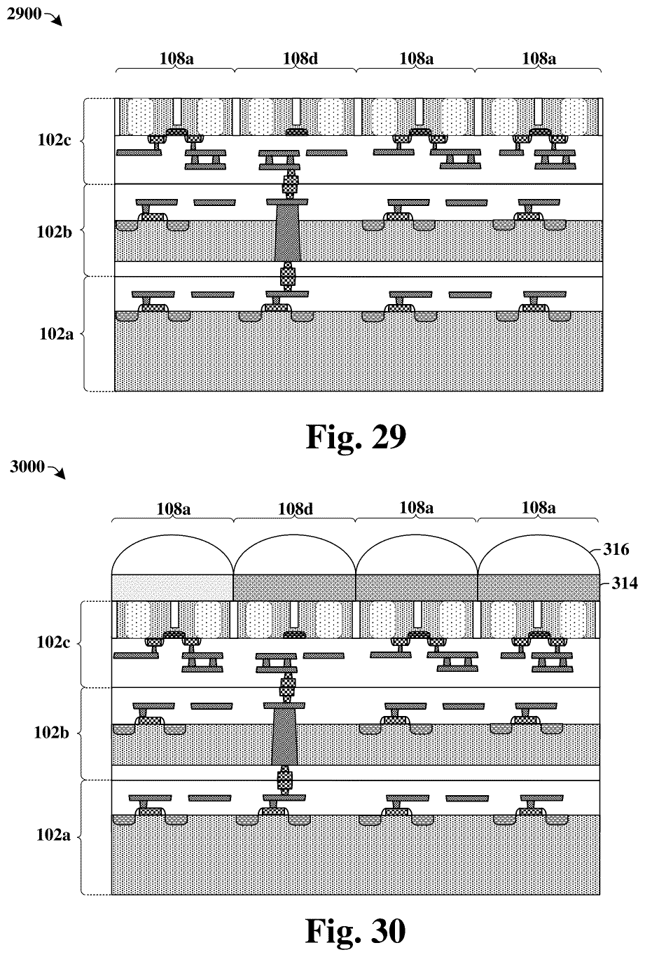

As shown in cross-sectional view 2900 of FIG. 29, the one or more integrated chip die 2802 are removed from the piece of dicing tape (2804 of FIG. 28).

As shown in cross-sectional view 3000 of FIG. 30, a plurality of color filters 314 are formed over the first substrate 104a. In some embodiments, the plurality of color filters 314 are formed by depositing (e.g., via CVD, PVD, ALD, sputtering, a spin-on process, etc.) a light filtering material(s) onto the first substrate 104a. The light filtering material(s) is a material that allows for the transmission of radiation (e.g., light) having a specific wavelength range, while blocking light of wavelengths outside of the specified range. Subsequently, in some embodiments, a planarization process (e.g., CMP) may be performed on the plurality of color filters 314 to planarize the upper surfaces of the plurality of color filters 314.

A plurality of micro-lenses 316 are formed over the plurality of color filters 314. In some embodiments, the plurality of micro-lenses 316 may be formed by depositing a micro-lens material on the plurality of color filters 314 (e.g., via CVD, PVD, ALD, sputtering, a spin-on process, etc.). A micro-lens template (not shown) having a curved upper surface is patterned above the micro-lens material. In some embodiments, the micro-lens template may comprise a photoresist material exposed using a distributing exposing light dose (e.g., for a negative photoresist more light is exposed at a bottom of the curvature and less light is exposed at a top of the curvature), developed, and baked to form a rounding shape. The plurality of micro-lenses 316 are then formed by selectively etching the micro-lens material according to the micro-lens template.

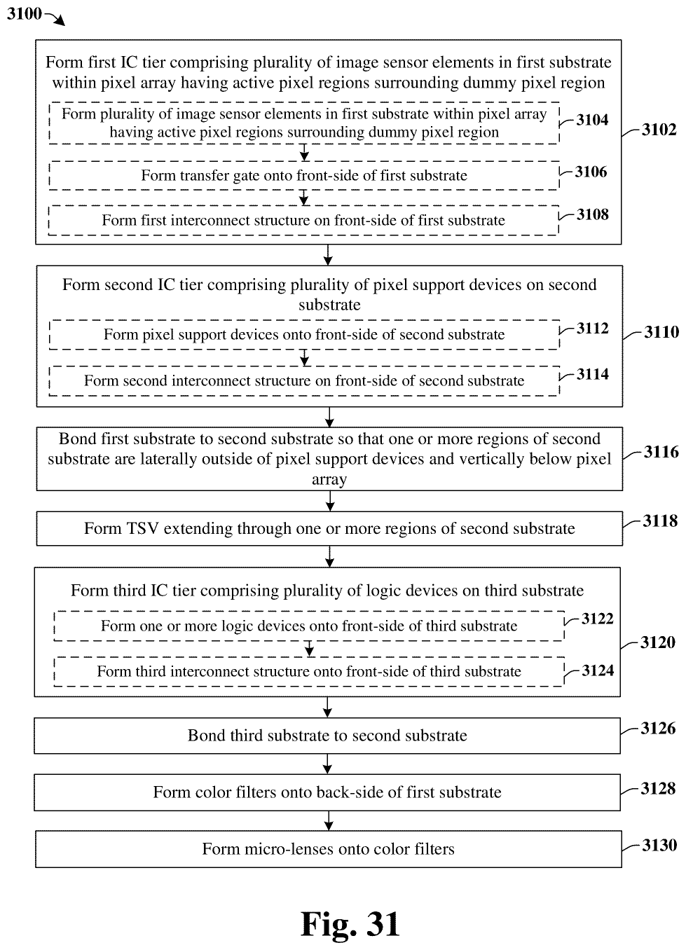

FIG. 31 illustrates a flow diagram of some embodiments of a method 3100 of forming an image sensor integrated chip structure comprising a TSV located below a pixel array comprising a dummy pixel region.

While the disclosed methods (e.g., methods 3100 and 5200) are illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases

At act 3102, a first IC tier is formed to comprise a plurality of image sensing elements within a pixel array within a first substrate. The pixel array comprises a plurality of active pixel regions surrounding one or more dummy pixel regions. In some embodiments, the first IC tier may be formed according to acts 3104-3108.

At act 3104, a plurality of image sensing elements are formed in a first substrate within a pixel array having a plurality of active pixel regions surrounding one or more dummy pixel regions. FIG. 11 illustrates a cross-sectional view 1100 of some embodiments corresponding to act 3104.

At act 3106, a transfer gate is formed onto a front-side of the first substrate. FIG. 12 illustrates a cross-sectional view 1200 of some embodiments corresponding to act 3106.

At act 3108, a first interconnect structure is formed onto the front-side of the first substrate. FIG. 12 illustrates a cross-sectional view 1200 of some embodiments corresponding to act 3108.

At act 3110, a second IC tier is formed to comprise a plurality of pixel support devices on a second substrate. In some embodiments, the second IC tier may be formed according to acts 3112-3114.

At act 3112, a plurality of pixel support devices are formed on a second substrate. FIG. 14 illustrates a cross-sectional view 1400 of some embodiments corresponding to act 3112.

At act 3114, a second interconnect structure is formed onto the front-side of the second substrate. FIG. 15 illustrates a cross-sectional view 1500 of some embodiments corresponding to act 3114.

At act 3116, the first substrate is bonded to the second substrate so that one or more regions of second substrate are laterally outside of the pixel support devices and vertically below the pixel array. FIG. 16 illustrates a cross-sectional view 1600 of some embodiments corresponding to act 3116.

At act 3118, a through-substrate-via (TSV) is formed to extend through the one or more regions of second substrate. FIG. 18 illustrates a cross-sectional view 1800 of some embodiments corresponding to act 3118.

At act 3120, a third IC tier is formed to comprise a plurality of logic devices on a third substrate. In some embodiments, the third IC tier may be formed according to acts 3122-3124.

At act 3122, a plurality of logic devices are formed on the third substrate. FIG. 22 illustrates a cross-sectional view 2200 of some embodiments corresponding to act 3122.

At act 3124, a third interconnect structure is formed onto the front-side of the third substrate. FIG. 23 illustrates a cross-sectional view 2300 of some embodiments corresponding to act 3124.

At act 3126, the third substrate is bonded to the second substrate. FIG. 24 illustrates a cross-sectional view 2400 of some embodiments corresponding to act 3126.

At act 3128, a plurality of color filters are formed onto a back-side of the first substrate. FIG. 30 illustrates a cross-sectional view 3000 of some embodiments corresponding to act 3128.

At act 3130, a plurality of micro-lenses are formed onto the plurality of color filters. FIG. 30 illustrates a cross-sectional view 3000 of some embodiments corresponding to act 3130.

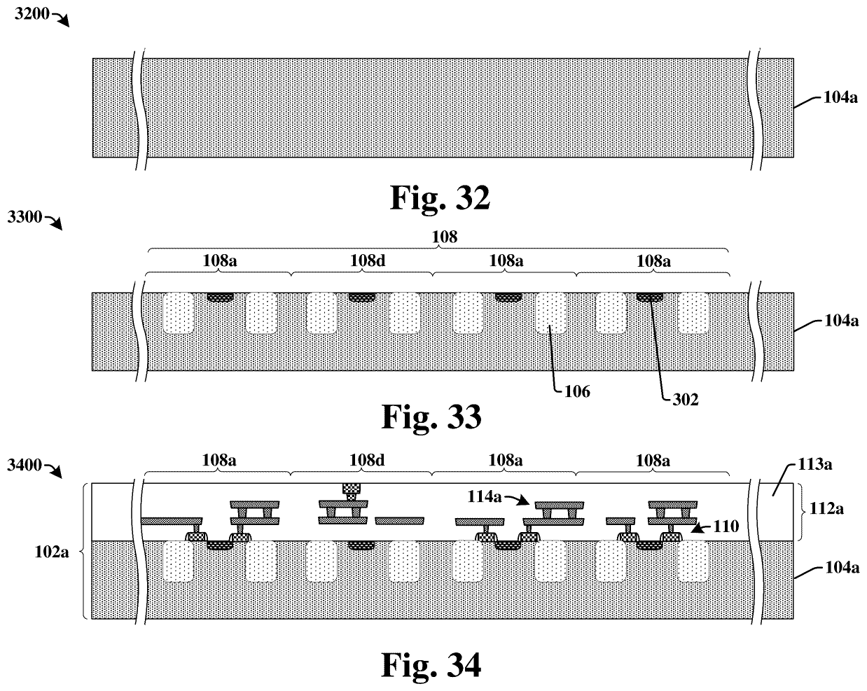

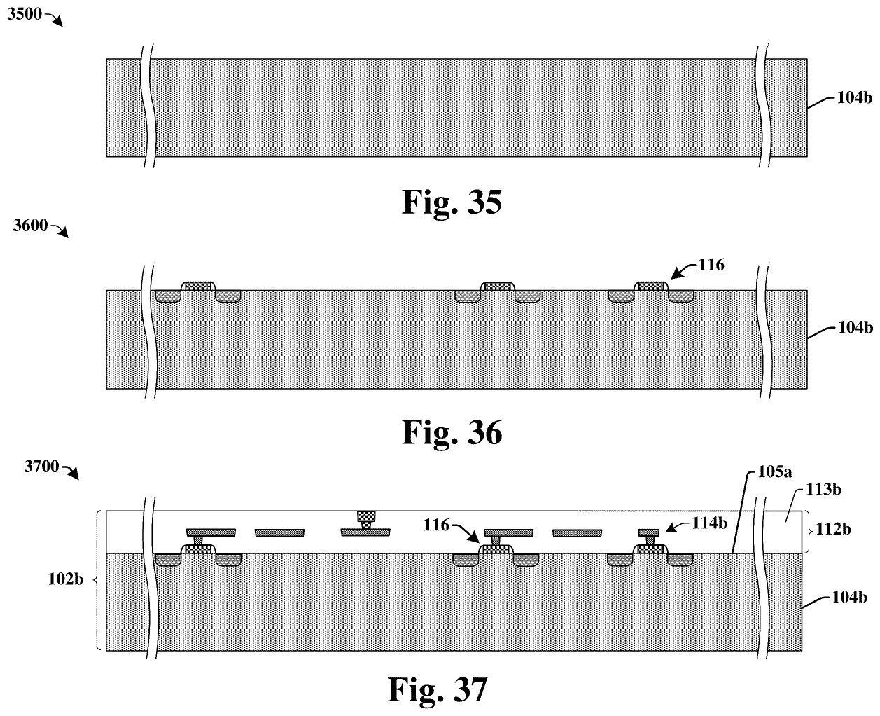

FIGS. 32-51 illustrate cross-sectional views of some additional embodiments of a method of forming a multi-dimensional image sensor integrated chip structure comprising a TSV located below a pixel array comprising a dummy pixel region. Although FIGS. 32-51 are described in relation to a method, it will be appreciated that the structures disclosed in the method are not limited to the method, but instead may stand alone as structures independent of the method.

As shown in cross-sectional view 3200 of FIG. 32, a first substrate 104a is provided.

As shown in cross-sectional view 3300 of FIG. 33, a plurality of image sensing elements 106 are formed within a plurality of pixel regions, 108a and 108d, in a pixel array 108 within the first substrate 104a. In some embodiments, the plurality of pixel regions, 108a and 108d, may comprise a plurality of active pixel regions 108a and one or more dummy pixel regions 108d. In some embodiments a floating diffusion region 302 may also be formed within the first substrate 104a.

As shown in cross-sectional view 3400 of FIG. 34, a plurality of transfer gates 110 are formed along a front-side of the first substrate 104a and within the plurality of active pixel regions 108a. A first interconnect structure 112a is formed onto a front-side of the first substrate 104a. The first interconnect structure 112a comprises a first plurality of interconnects 114a formed within a first ILD structure 113a comprising one or more ILD layers.

As shown in cross-sectional view 3500 of FIG. 13, a second substrate 104b is provided.

As shown in cross-sectional view 3600 of FIG. 36, a plurality of pixel support devices 116 are formed on and/or within the second substrate 104b. In some embodiments, the plurality of pixel support devices 116 may comprise a reset transistor, a source-follower transistor, a row-select transistor, and/or the like.

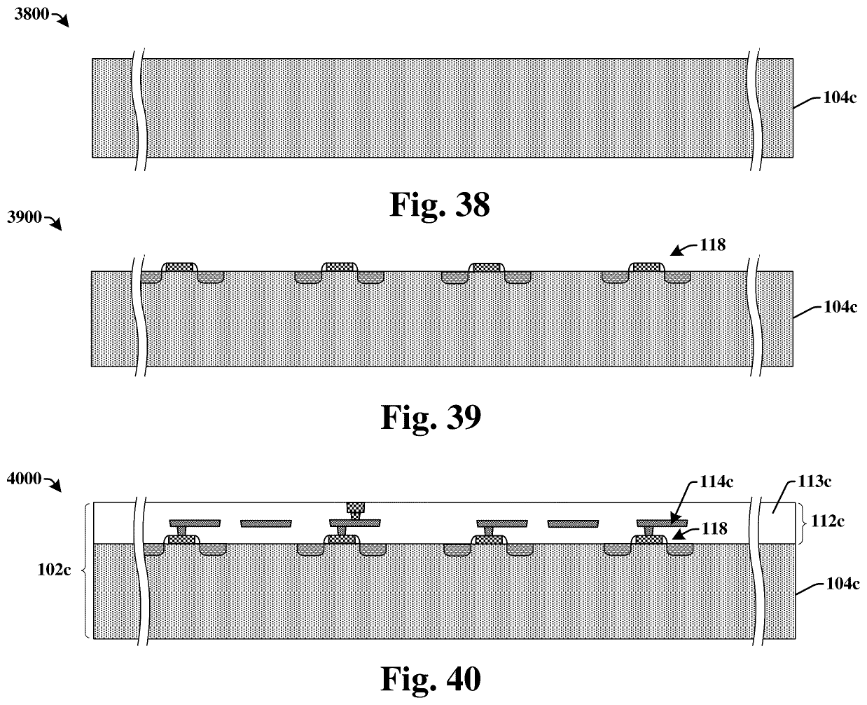

As shown in cross-sectional view 3700 of FIG. 37, a second interconnect structure 112b is formed onto a front-side 105a of the second substrate 104b. The second interconnect structure 112b comprises a second plurality of interconnects 114b formed within a second ILD structure 113b comprising one or more ILD layers.

As shown in cross-sectional view 3800 of FIG. 38, a third substrate 104c is provided. In various embodiments, the third substrate 104c may be any type of semiconductor body (e.g., silicon, SiGe, etc.), such as a semiconductor wafer and/or one or more die on a wafer, as well as any other type of semiconductor and/or epitaxial layers, associated therewith.

As shown in cross-sectional view 3900 of FIG. 39, a plurality of logic devices 118 are formed on and/or within the third substrate 104c.

As shown in cross-sectional view 4000 of FIG. 40, a third interconnect structure 112c is formed onto a front-side of the third substrate 104c. The third interconnect structure 112c comprises a third plurality of interconnects 114c formed within a third ILD structure 113c comprising one or more ILD layers.

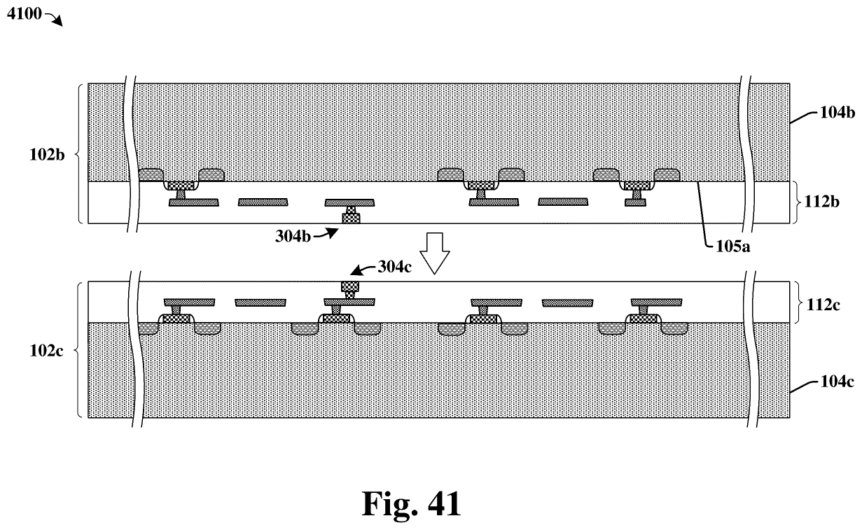

As shown in cross-sectional view 4100 of FIG. 41, the second substrate 104b is bonded to the third substrate 104c. In various embodiments, the second substrate 104b may be bonded to the third substrate 104c by way of a bonding process that forms a bonding interface comprising a dielectric interface and a metal interface.

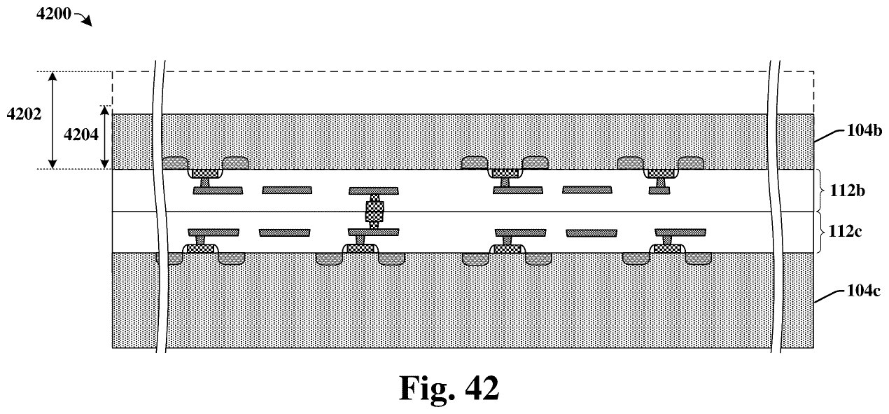

As shown in cross-sectional view 4200 of FIG. 42, a thickness of the second substrate 104b is reduced. In some embodiments, the thickness of the second substrate 104b may be reduced from a first thickness 4202 to a second thickness 4204 that is less than the first thickness 4202.

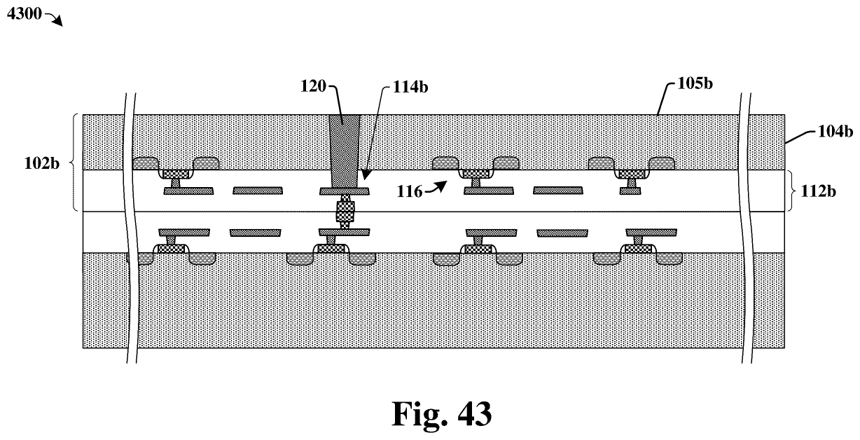

As shown in cross-sectional view 4300 of FIG. 43, a TSV 120 is formed to extend through the second substrate 104b within one or more regions that are laterally outside of the pixel support devices 116. The TSV 120 is formed by performing an etching process to selectively etch through the second substrate 104b and/or the second interconnect structure 112b to form a TSV opening exposing one of the second plurality of interconnects 114b. In some embodiments, the etching process may expose a back-side 105b of the second substrate 104b to an etchant. A conductive material is subsequently formed within the TSV opening followed by a planarization process (e.g., a CMP process).

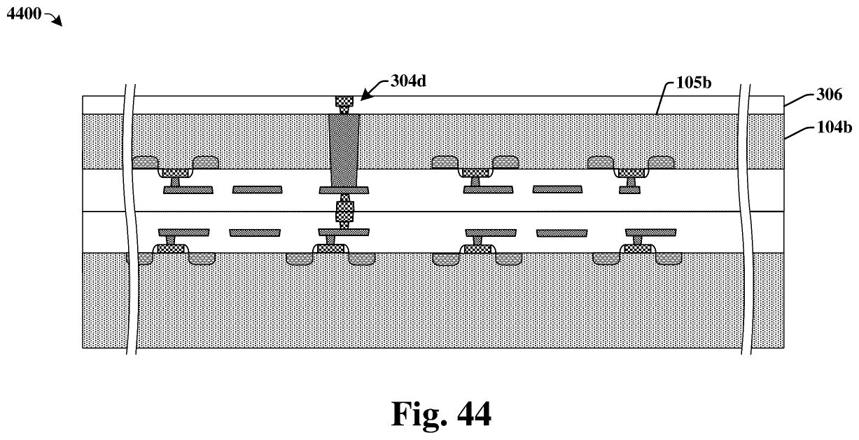

As shown in cross-sectional view 4400 of FIG. 44, an additional conductive bonding structure 304d is formed within an additional dielectric structure 306 formed onto the back-side 105b of the second substrate 104b.

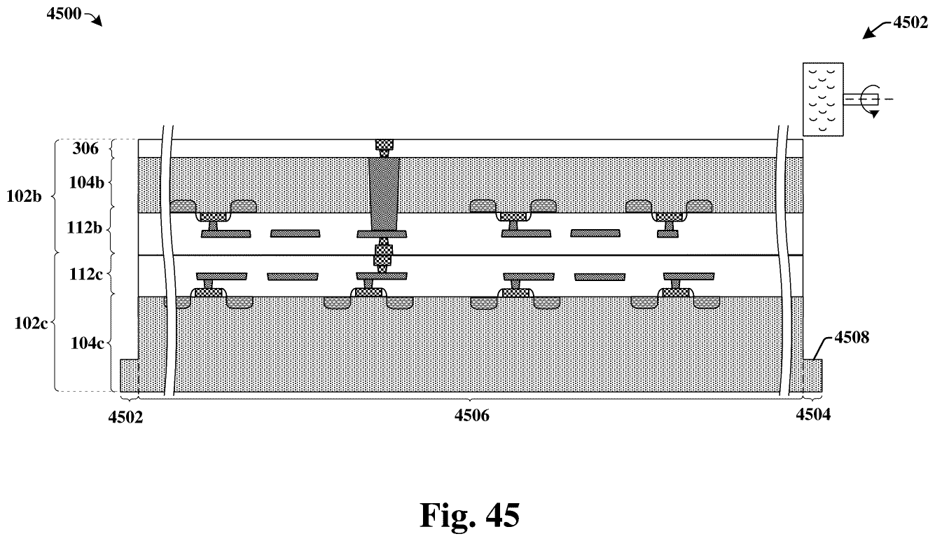

As shown in cross-sectional view 4500 of FIG. 45, a first edge trimming cut is performed on the third substrate 104c and the second substrate 104b. The first edge trimming cut removes peripheral portions 4504 of the third substrate 104c and the second substrate 104b that surround a central portion 4506 of the third substrate 104c and the second substrate 104b. In some embodiments, the first edge trimming cut forms a recessed upper surface 4508 within the third substrate 104c. In some embodiments, the first edge trimming cut may be performed by bringing a first blade 4502 into contact with the second substrate 104b along a closed loop.

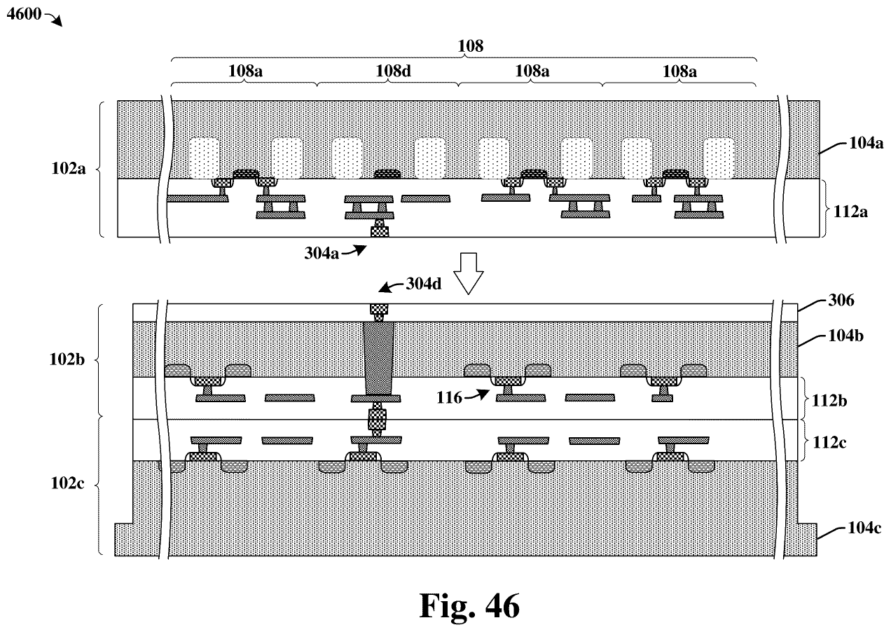

As shown in cross-sectional view 4600 of FIG. 46, the first substrate 104a is bonded to the additional dielectric structure 306 to form a semiconductor structure that has the TSV 120 within the one or more regions laterally outside of the pixel support devices 116 and directly below the pixel array 108. In some embodiments, the TSV 120 may be directly below the dummy pixel region 108d. In various embodiments, the first substrate 104a may be bonded to the additional dielectric structure 306 by way of a bonding process that forms a bonding interface comprising a dielectric interface and a metal interface.

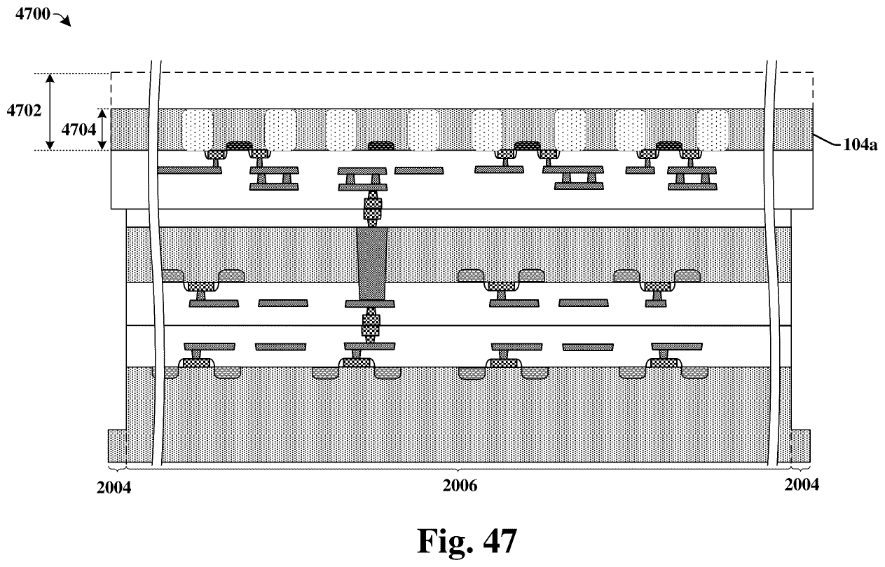

As shown in cross-sectional view 4700 of FIG. 47, a thickness of the first substrate 104a is reduced. In some embodiments, the thickness of the first substrate 104a may be reduced by performing a second grinding process on the first substrate 104a to reduce the thickness of the first substrate 104a from a first thickness 4702 to a second thickness 4704 that is less than the first thickness 4702.

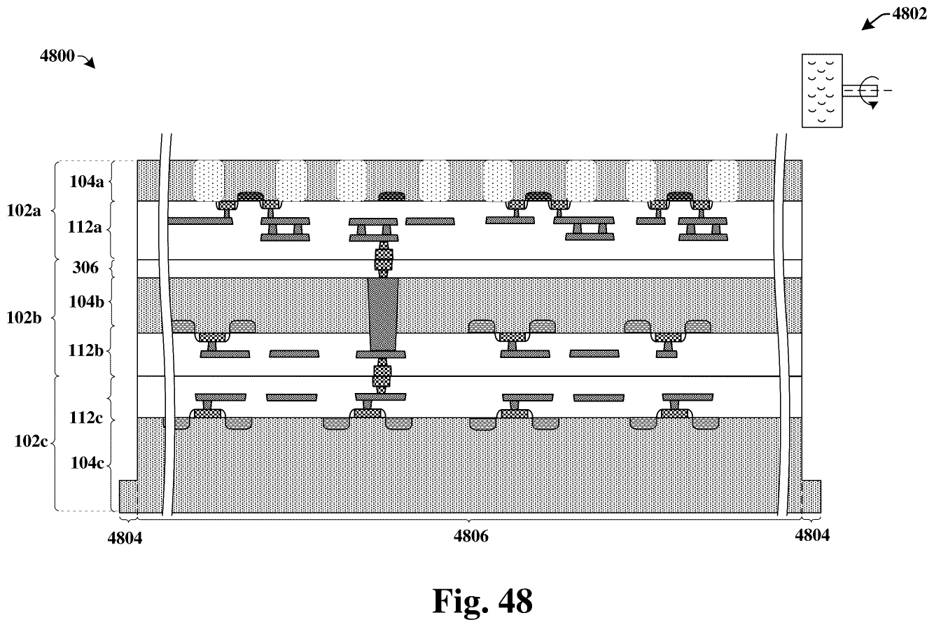

As shown in cross-sectional view 4800 of FIG. 48, a second edge trimming cut is performed into a peripheral portion 4804 of the first substrate 104a surrounding a central portion 4806 of the first substrate 104a. The second edge trimming cut removes the peripheral portion 4804 of the first substrate 104a. In some embodiments, the second edge trimming cut may be performed by bringing a second blade 4802 into contact with the first substrate 104a along a closed loop.

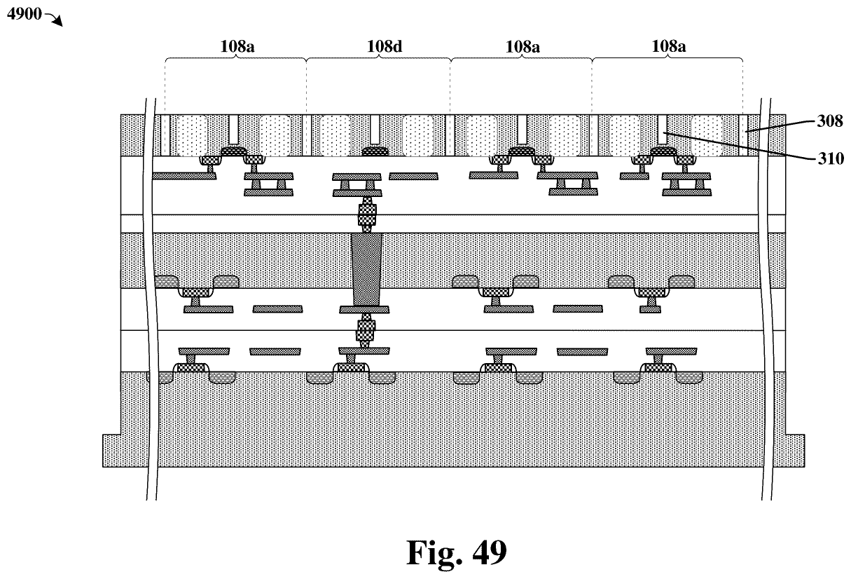

As shown in cross-sectional view 4900 of FIG. 49, an isolation structure 308 is formed within a back-side of the first substrate 104a along opposing sides of the plurality of pixel regions, 108a and 108d. In some embodiments, the isolation structure 308 may be formed by forming one or more dielectric materials within one or more trenches 2602 etched along the back-side of the first substrate 104a. In some embodiments, one or more additional isolation regions 310 may be formed within the back-side of the first substrate 104a over the diffusion region 302.

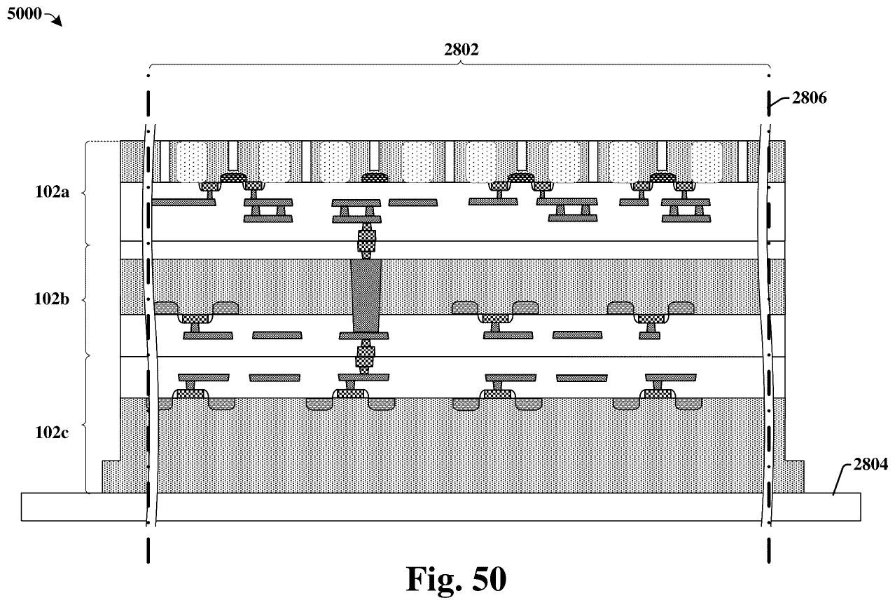

As shown in cross-sectional view 5000 of FIG. 50, the semiconductor structure is singulated to form one or more integrated chip die 2802. In some embodiments, the semiconductor structure may be singulated by a dicing process that mounts the semiconductor structure onto a sticky surface of a piece of dicing tape 2804. A wafer saw then cuts the wafer along scribe lines 2806 to separate the wafer into the one or more integrated chip die 2802.

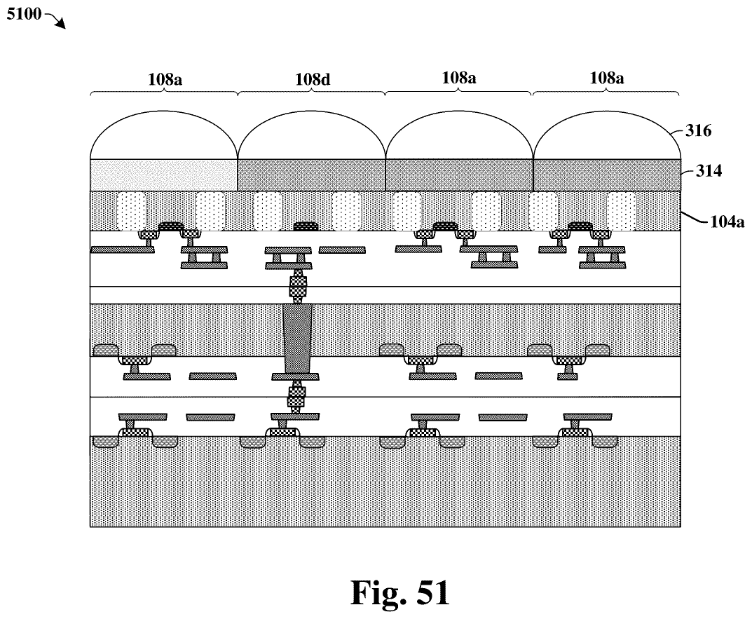

As shown in cross-sectional view 5100 of FIG. 51, a plurality of color filters 314 are formed over the first substrate 104a. A plurality of micro-lenses 316 are formed over the plurality of color filters 314.

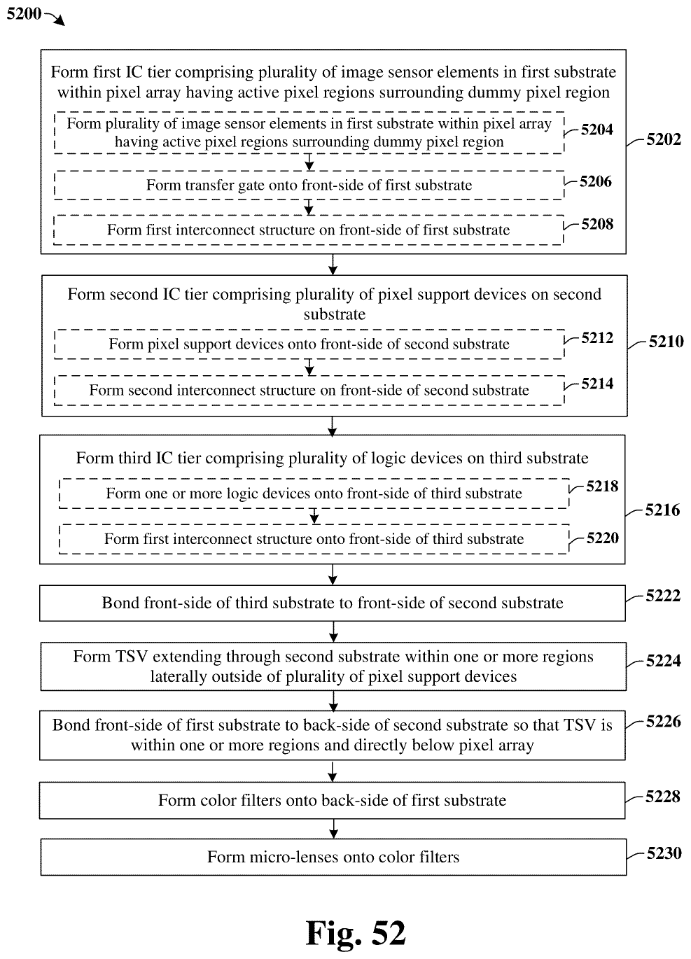

FIG. 52 illustrates a flow diagram of some additional embodiments of a method 5200 of forming an image sensor integrated chip structure comprising a TSV located below a pixel array comprising a dummy pixel region.

At act 5202, a first IC tier is formed to comprise a plurality of image sensing elements within a pixel array within a first substrate. The pixel array comprises a plurality of active pixel regions surrounding one or more dummy pixel regions. In some embodiments, the first IC tier may be formed according to acts 5204-5208.

At act 5204, a plurality of image sensing elements are formed in a first substrate within a pixel array having a plurality of active pixel regions surrounding one or more dummy pixel regions. FIG. 33 illustrates a cross-sectional view 3300 of some embodiments corresponding to act 5204.

At act 5206, a transfer gate is formed onto a front-side of the first substrate. FIG. 34 illustrates a cross-sectional view 3400 of some embodiments corresponding to act 5206.

At act 5208, a first interconnect structure is formed onto the front-side of the first substrate. FIG. 34 illustrates a cross-sectional view 3400 of some embodiments corresponding to act 5208.

At act 5210, a second IC tier is formed to comprise a plurality of pixel support devices on a second substrate. In some embodiments, the second IC tier may be formed according to acts 5212-5214.

At act 5212, a plurality of pixel support devices are formed on a front-side of the second substrate. FIG. 36 illustrates a cross-sectional view 3600 of some embodiments corresponding to act 5212.

At act 5214, a second interconnect structure is formed onto the front-side of the second substrate. FIG. 37 illustrates a cross-sectional view 3700 of some embodiments corresponding to act 5214.

At act 5216, a third IC tier is formed to comprise a plurality of logic devices on a third substrate. In some embodiments, the third IC tier may be formed according to acts 5218-5216.

At act 5218, a plurality of logic devices are formed on the third substrate. FIG. 39 illustrates a cross-sectional view 3900 of some embodiments corresponding to act 5218.

At act 5220, a third interconnect structure is formed onto the front-side of the third substrate. FIG. 40 illustrates a cross-sectional view 4000 of some embodiments corresponding to act 5220.

At act 5222, the front-side of the third substrate is bonded to the front-side of the second substrate. FIG. 41 illustrates a cross-sectional view 4100 of some embodiments corresponding to act 5222.

At act 5224, a through-substrate-via (TSV) is formed to extend through one or more regions of the second substrate that are laterally outside of the one or more pixel support devices. FIG. 43 illustrates a cross-sectional view 4300 of some embodiments corresponding to act 5224.

At act 5226, a front-side of the first substrate is bonded to a back-side of the second substrate so that the TSV is within the one or more regions and directly below the pixel array. FIG. 46 illustrates a cross-sectional view 4600 of some embodiments corresponding to act 5226.

At act 5228, a plurality of color filters are formed onto a back-side of the first substrate. FIG. 51 illustrates a cross-sectional view 5100 of some embodiments corresponding to act 5228.

At act 5230, a plurality of micro-lenses are formed onto the plurality of color filters. FIG. 51 illustrates a cross-sectional view 5100 of some embodiments corresponding to act 5230.

Accordingly, the present disclosure relates to a multi-dimensional image sensor integrated chip (IC) structure that has one or more through substrate vias (TSVs) arranged directly below a pixel array having one or more dummy pixel regions.

In some embodiments, the present disclosure relates to a multi-dimensional image sensor integrated chip (IC) structure. The multi-dimensional image sensor IC structure includes a plurality of image sensing elements disposed within a plurality of pixel regions arranged in a pixel array of a first integrated chip (IC) tier, the plurality of pixel regions including a plurality of active pixel regions and one or more dummy pixel regions; a plurality of pixel support devices disposed on a second substrate within a second IC tier that is bonded to the first IC tier; a plurality of logic devices disposed within a third IC tier that is bonded to the second IC tier; and a through substrate via (TSV) extending vertically through the second substrate laterally outside of the plurality of pixel support devices and directly below the pixel array. In some embodiments, the multi-dimensional image senor IC structure further includes a plurality of transfer gates arranged on a first substrate of the first IC tier and respectively disposed within one of the plurality of active pixel regions, the TSV being laterally between a first transfer gate and a second transfer gate of the plurality of transfer gates, as viewed in a cross-sectional view. In some embodiments, the multi-dimensional image sensor IC structure further includes one or more dummy image sensing elements disposed within the one or more dummy pixel regions, the one or more dummy image sensing elements being electrically isolated from the plurality of pixel support devices. In some embodiments, the first IC tier includes a first interconnect structure disposed on a first substrate, the first interconnect structure being devoid of interconnects directly below the one or more dummy pixel regions. In some embodiments, the one or more dummy pixel regions are laterally surrounded by the plurality of active pixel regions along a first direction and along a second direction that is perpendicular to the first direction as viewed in a top-view of the pixel array. In some embodiments, the multi-dimensional image sensor IC structure further includes one or more peripheral TSV vertically extending through the second substrate at one or more locations that are laterally outside of the pixel array. In some embodiments, the plurality of active pixel regions have a first width and the one or more dummy pixel regions have a second width measured along a cross-sectional view, the first width being different than the second width. In some embodiments, the multi-dimensional image sensor IC structure further includes one or more additional through substrate vias (TSVs) extending vertically through the second substrate laterally outside of the plurality of pixel support devices and directly below the pixel array, the TSV and the one or more additional TSVs being arranged between adjacent ones of the plurality of active pixel regions along a cross-sectional view. In some embodiments, the TSV vertically extends through the second substrate directly below the one or more dummy pixel regions. In some embodiments, the multi-dimensional image sensor IC structure further includes one or more transfer gates arranged on a first substrate of the first IC tier and within respective ones of the plurality of active pixel regions, the first substrate being devoid of transfer gates within the one or more dummy pixel regions.

In other embodiments, the present disclosure relates to an image sensor IC structure. The image sensor IC structure includes a pixel array having a plurality of image sensing elements disposed within a plurality of pixel regions of a first substrate, the plurality of pixel regions including a plurality of active pixel regions laterally surrounding one or more dummy pixel regions; a plurality of pixel support devices disposed within a second substrate stacked on the first substrate and coupled to a second interconnect structure on the second substrate, the plurality of active pixel regions respectively including one or more of the plurality of image sensing elements that are electrically coupled to the plurality of pixel support devices; a plurality of logic devices disposed on a third substrate stacked on the second substrate and coupled to a third interconnect structure on the third substrate; and a through substrate via (TSV) extending vertically through the second substrate directly below the pixel array and laterally outside of the plurality of pixel support devices. In some embodiments, the plurality of pixel support devices are arranged directly below the plurality of active pixel regions and the TSV is arranged directly below the one or more dummy pixel regions. In some embodiments, the plurality of pixel support devices are arranged directly below the one or more dummy pixel regions and the TSV is arranged directly below the plurality of active pixel regions. In some embodiments, the TSV is part of a TSV array arranged between sides of the plurality of active pixel regions facing one another. In some embodiments, the one or more dummy pixel regions include one or more dummy image sensing elements of the plurality of image sensing elements, the one or more dummy image sensing elements being electrically isolated from the plurality of pixel support devices. In some embodiments, the TSV electrically connects the second interconnect structure to the third interconnect structure.

In yet other embodiments, the present disclosure relates to a method of forming an image sensor IC structure. The method includes forming a first integrated chip (IC) tier having a plurality of image sensing elements within a pixel array in a first substrate, the pixel array including a plurality of active pixel regions surrounding one or more dummy pixel regions; forming a second IC tier comprising a plurality of pixel support devices on a second substrate; bonding the first IC tier to the second IC tier so that one or more regions of the second substrate are laterally outside of the plurality of pixel support devices and vertically below the pixel array; forming a through substrate via (TSV) to extend through the one or more regions of the second substrate; forming a third IC tier including a plurality of logic devices on a third substrate; and bonding the third IC tier to the second IC tier. In some embodiments, the method further includes bonding a front-side of the first substrate to a front-side of the second substrate; and bonding a front-side of the third substrate to a back-side of the second substrate. In some embodiments, the method further includes etching the back-side of the second substrate to form a TSV opening extending through the second substrate; and forming the TSV within the TSV opening. In some embodiments, the plurality of image sensing elements include one or more dummy image sensing elements within the one or more dummy pixel regions, the TSV being directly below the one or more dummy image sensing elements after bonding the first substrate to the second substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-20. (canceled)

21. An integrated chip structure, comprising:
a plurality of isolation structures extending through a first substrate along opposing sides of respective ones of a plurality of pixel regions within a pixel array;
a first plurality of gate structures arranged on the first substrate within one or more of the plurality of pixel regions and coupled to a first plurality of interconnects within a first dielectric structure on the first substrate;
a second plurality of gate structures disposed on a second substrate bonded to the first substrate, wherein the second plurality of gate structures are coupled to a second plurality of interconnects within a second dielectric structure on the second substrate;
a plurality of logic devices disposed within a third substrate that is bonded to the second substrate, wherein the plurality of logic devices are coupled to a third plurality of interconnects within a third dielectric structure on the third substrate; and
a conductive structure vertically extending through the second substrate laterally outside of the second plurality of gate structures and directly below a first pixel region of the plurality of pixel regions.

22. The integrated chip structure of claim 21, wherein the plurality of pixel regions comprise a second pixel region having a first gate structure of the first plurality of gate structures, wherein the first pixel region is devoid of the first plurality of gate structures.

23. The integrated chip structure of claim 21, wherein the first dielectric structure and the second dielectric structure are vertically between the first substrate and the second substrate.

24. The integrated chip structure of claim 21, wherein the second dielectric structure and the third dielectric structure are vertically between the second substrate and the third substrate.

25. The integrated chip structure of claim 21,
wherein the plurality of pixel regions include a plurality of active pixel regions and a plurality of dummy pixel regions, at least two of the plurality of dummy pixel regions are disposed in different rows and different columns;
wherein the first pixel region is one of the plurality of dummy pixel regions; and
wherein a second conductive structure vertically extends through the second substrate within another one of the plurality of dummy pixel regions.

26. The integrated chip structure of claim 21, further comprising:
a second conductive structure extending through the second substrate at a location outside of the pixel array.

27. The integrated chip structure of claim 26, wherein the conductive structure has a smaller size than the second conductive structure.

28. The integrated chip structure of claim 21, further comprising:
additional conductive structures extending through the second substrate directly below the first pixel region, wherein the conductive structure and the additional conductive structures are arranged in an array having rows and columns.

29. The integrated chip structure of claim 21, wherein the first dielectric structure has a surface that completely covers the first substrate within the first pixel region.

30. An integrated chip structure, comprising:
a plurality of semiconductor devices disposed within a plurality of device regions arranged in an array on a first semiconductor substrate;
a plurality of support devices disposed on a second semiconductor substrate that is bonded to the first semiconductor substrate;
a plurality of logic devices disposed within a third semiconductor substrate that is bonded to the second semiconductor substrate; and
a through substrate via (TSV) extending vertically through the second semiconductor substrate and laterally between outermost edges of the array.

31. The integrated chip structure of claim 30, wherein the TSV extends through the second semiconductor substrate within a part of the second semiconductor substrate that is below a first device region of the plurality of device regions and that is devoid of the plurality of support devices in a cross-sectional view.

32. The integrated chip structure of claim 30, further comprising:
a second TSV extending vertically through the second semiconductor substrate, wherein one or more of the plurality of support devices are laterally between the TSV and the second TSV in a cross-sectional view.

33. The integrated chip structure of claim 30, wherein the plurality of device regions comprise a plurality of pixel regions, the TSV being directly below a dummy pixel region having no light-sensitive functionality.

34. The integrated chip structure of claim 30, wherein the plurality of device regions comprise a plurality of pixel regions, the TSV being directly below a dummy pixel region that does not comprise an image sensing element configured to generate a current that is provided to the plurality of support devices in response to incident radiation.

35. An integrated chip structure, comprising:
a plurality of pixel regions arranged in a first semiconductor substrate in a pixel array extending along a first direction and along a second direction, the second direction being perpendicular to the first direction in a top view;
a plurality of pixel support devices comprising gate structures disposed on a second semiconductor substrate below the pixel array in a cross-sectional view; and
a through substrate via (TSV) extending vertically through the second semiconductor substrate below a first pixel region of the plurality of pixel regions within the pixel array, wherein the plurality of pixel support devices laterally surround opposing sides of the TSV along the first direction and along the second direction.

36. The integrated chip structure of claim 35, wherein the first semiconductor substrate is bonded to the second semiconductor substrate in a face-to-face configuration.

37. The integrated chip structure of claim 35, wherein the first semiconductor substrate is bonded to the second semiconductor substrate in a face-to-back configuration.

38. The integrated chip structure of claim 35, further comprising:
a plurality of logic devices disposed within a third semiconductor substrate, wherein the second semiconductor substrate is bonded between the first semiconductor substrate and the third semiconductor substrate.

39. The integrated chip structure of claim 35, further comprising:
a plurality of TSVs arranged directly below the first pixel region, wherein the TSV and the plurality of TSVs are arranged in an array having rows and columns.

40. The integrated chip structure of claim 39, further comprising:
an additional TSV arranged directly below a second pixel region of the plurality of pixel regions, wherein the additional TSV has a larger width than respective ones of the TSV and the plurality of TSVs.
